(19) United States
(12) Patent Application Publication
(10) Pub. No.: US 2024/0404931 A1
(43) Pub. Date: Dec. 5, 2024

(54) METHOD OF MANUFACTURING SEMICONDUCTOR PACKAGES

(71) Applicant: SAMSUNG ELECTRONICS CO., LTD., Suwon-si (KR)

(72) Inventors: Hyejin LEE, Suwon-si (KR); Jihye SHIN, Suwon-si (KR); Kihyun KIM, Suwon-si (KR)

(73) Assignee: SAMSUNG ELECTRONICS CO., LTD., Suwon-si (KR)

(21) Appl. No.: 18/436,993

(22) Filed: Feb. 8, 2024

(30) Foreign Application Priority Data
Jun. 1, 2023 (KR) 10-2023-0070818

(51) Int. Cl. H01L 23/498; H01L 21/027; H01L 21/311; H01L 23/00; H01L 25/065; H10B 80/00

(52) U.S. Cl. CPC H01L 23/49822; H01L 21/0274; H01L 21/31144; H01L 23/49816; H01L 24/05; H01L 24/45; H01L 25/0657; H01L 2224/05009; H01L 2224/05024; H01L 2224/45005; H01L 2224/4502; H01L 2225/06506; H01L 2225/06562; H01L 2924/1431; H01L 2924/1434; H01L 2924/15311; H01L 2924/182; H10B 80/00

(57) ABSTRACT

A method includes: forming a first photoresist layer on a first insulating layer; forming a first photoresist pattern having first opening patterns using a first exposure mask; etching the first insulating layer using the first photoresist pattern to form first via holes; removing the first photoresist pattern; forming a second photoresist layer on the first insulating layer; forming a second photoresist pattern having second opening patterns using a second exposure mask; etching the first insulating layer using the second photoresist pattern to form second via holes; removing the first photoresist pattern; forming a redistribution wiring layer on the first insulating layer, the redistribution wiring layer having first redistribution wirings connected to first bonding pads under the first insulating layer through the via holes; and mounting a semiconductor chip on the redistribution wiring layer, the semiconductor chip comprising chip pads connected to the first redistribution wirings.

### CROSS-REFERENCE TO RELATED APPLICATIONS

This application is based on claims priority under 35 U.S.C. § 119 to Korean Patent Application No. 10-2023-0070818, filed on Jun. 1, 2023 in the Korean Intellectual Property Office (KIPO), the disclosure of which is incorporated by reference herein in its entirety.

### BACKGROUND

### 1. Field

The disclosure relates to a method of manufacturing a semiconductor package. In particular, the disclosure relates to a method of manufacturing a wafer level semiconductor package.

### 2. Description of the Related Art

A redistribution wiring layer of a wafer level package may include a plurality of insulating layers and redistribution wirings that are stacked in at least two layers in the plurality insulating layers. As the redistribution wirings have a fine line width, diameters and pitches of via holes, which are electrically connected with the redistribution wirings, may also need to become smaller. In the related art, in a case that the insulating layer (among the plurality of insulating layers) of the redistribution wiring layer includes a photosensitive insulating layer (PID), because a resolution of the insulating layer (including the PID) is lower than a resolution of an existing photoresist pattern, it may be difficult to form fine via holes in the insulating layer (including the PID).

### SUMMARY

Provided is a method of manufacturing a semiconductor package including a redistribution wiring layer having fine redistribution wirings.

According to an aspect of the disclosure, a method of manufacturing a semiconductor package, includes: forming a plurality of lower redistribution wiring layers including first redistribution wirings stacked in at least two layers of the plurality of lower redistribution wiring layers; mounting a semiconductor chip on the plurality of lower redistribution wiring layers, the semiconductor chip including chip pads that are electrically connected to the first redistribution wirings; forming a sealing member covering the semiconductor chip on the plurality of lower redistribution wiring layers; forming a plurality of through-vias penetrating the sealing member, the plurality of through-vias being electrically connected to the first redistribution wirings; and forming a plurality of upper redistribution wiring layers on the sealing member, the plurality of upper redistribution wiring layers including second redistribution wirings electrically connected to the plurality of through-vias, wherein the forming the plurality of lower redistribution wiring layers includes: forming a first insulating layer; performing a first photo etching process on the first insulating layer to form first via holes; performing a second photo etching process on the first insulating layer to form second via holes; and forming first lower redistribution wirings on the first insulating layer, the first lower redistribution wirings being electrically connected to first bonding pads under the first insulating layer through the first via hole and the second via hole.

In an embodiment, the first insulating layer may include a photosensitive insulating material.

In an embodiment, the forming the first insulating layer may include: coating a photosensitive insulating material layer of the first insulating layer; and performing a curing process on the photosensitive insulating material layer.

In an embodiment, the performing the first photo etching process on the first insulating layer may include: forming a first photoresist layer on the first insulating layer; performing an exposure process on the first photoresist layer using a first exposure mask; performing a development process to form a first photoresist pattern having first opening patterns corresponding to the first via holes; etching the first insulating layer using the first photoresist pattern as a first etching mask to form the first via holes; and removing the first photoresist pattern.

In an embodiment, the etching the first insulating layer to form the first via holes may include performing an isotropic etching process using the first photoresist pattern as the first etching mask on the first insulating layer.

In an embodiment, the performing the second photo etching process on the first insulating layer may include: forming a second photoresist layer on the first insulating layer; performing an exposure process on the second photoresist layer using a second exposure mask; and performing a development process to form a second photoresist pattern having second opening patterns corresponding to the second via holes; etching the first insulating layer using the second photoresist pattern as a second etching mask to form the second via holes; and removing the second photoresist pattern.

In an embodiment, the etching the first insulating layer to form the second via holes may include performing an isotropic etching process using the second photoresist pattern as the second etching mask on the first insulating layer.

In an embodiment, at least one sidewall of the first via hole and the second via hole may have an angle range of 85 degrees to 105 degrees with respect to a lower surface of the first insulating layer.

In an embodiment, at least one of the first via hole and the second via hole may have a diameter of 1 μm to 8 μm.

In an embodiment, the forming the plurality of upper redistribution wiring layers may include: forming a second insulating layer; performing a third photo etching process on the second insulating layer to form third via holes; performing a fourth photo etching process on a third insulating layer to form fourth via holes; and forming first upper redistribution wirings on the second insulating layer, the first upper redistribution wirings being electrically connected to second bonding pads under the second insulating layer through the third via hole and the fourth via hole.

According to an aspect of the disclosure, a method of manufacturing a semiconductor package, the method includes: providing a substrate including a plurality of semiconductor chips, each of the plurality of semiconductor chips including chip pads on a first surface of the semiconductor chip; forming a plurality of redistribution wiring layers on the first surface of the semiconductor chip, the plurality of redistribution wiring layers including redistribution wirings stacked in at least two layers of the plurality of redistribution wiring layers, the redistribution wiring being electrically connected to the chip pads; forming conductive bumps on an outer surface of the plurality of redistribution wiring layers; wherein the forming the plurality of redistribution wiring layers includes: forming a first insulating layer; performing a first photo etching process on the first insulating layer to form first via holes; performing a second photo etching process on the first insulating layer to form second via holes; and forming first lower redistribution wirings on the first insulating layer, the first lower redistribution wirings being electrically connected to first bonding pads under the first insulating layer through the first via hole and the second via hole.

In an embodiment, the first insulating layer may include photosensitive insulating material.

In an embodiment, the forming the first insulating layer may include: coating a photosensitive insulating material layer of the first insulating layer; and performing a curing process on the photosensitive insulating material layer.

In an embodiment, the performing the first photo etching process on the first insulating layer may include: forming a first photoresist layer on the first insulating layer; performing an exposure process on the first photoresist layer using a first exposure mask; performing a development process to form a first photoresist pattern having first opening patterns corresponding to the first via holes; etching the first insulating layer using the first photoresist pattern as a first etching mask to forming the first via holes; and removing the first photoresist pattern.

In an embodiment, the performing the second photo etching process on the first insulating layer may include: forming a second photoresist layer on the first insulating layer; exposing the second photoresist layer using a second exposure mask; performing exposure process to form a second photoresist pattern having second opening patterns corresponding to the second via holes; forming the second via holes by etching the first insulating layer using the second photoresist pattern as a second etching mask; and removing the second photoresist pattern.

In an embodiment, at least one sidewall of the first via hole and the second via hole may have an angle range of 85 degrees to 105 degrees with respect to a lower surface of the first insulating layer.

In an embodiment, at least one of the first via hole and the second via hole may have a diameter of 1 μm to 8 μm.

According to an aspect of the disclosure, a method of manufacturing a semiconductor package, the method includes: forming a first photoresist layer on a first insulating layer; forming a first photoresist pattern having first opening patterns using a first exposure mask; etching the first insulating layer using the first photoresist pattern as a first etching mask to form first via holes; removing the first photoresist pattern; forming a second photoresist layer on the first insulating layer; forming a second photoresist pattern having second opening patterns using a second exposure mask; etching the first insulating layer using the second photoresist pattern as a second etching mask to form second via holes; removing the first photoresist pattern; forming a redistribution wiring layer on the first insulating layer, the redistribution wiring layer having first redistribution wirings that are electrically connected to first bonding pads under the first insulating layer through the first via hole and the second via hole; and mounting a semiconductor chip on the redistribution wiring layer, the semiconductor chip including chip pads electrically connected to the first redistribution wirings.

In an embodiment, the first insulating layer may include a photosensitive insulating material.

In an embodiment, the forming the first insulating layer may include: coating a photosensitive insulating material layer of the first insulating layer; and performing a curing process on the photosensitive insulating material layer.

The openings of the insulating layer (including PID) may be formed through a double patterning process including two separate etching processes. The openings may be formed by dividing into first via holes and second via holes formed respectively by a first photo etching process and a second photo etching process, to thereby form the openings having relatively finer diameters and pitches. Thus, it may be possible to overcome the limitation of the resolution of the insulating layer (having the PID) being lower than the resolution of an existing photoresist pattern.

### BRIEF DESCRIPTION OF THE DRAWINGS

Example embodiments will be more clearly understood from the following detailed description taken in conjunction with the accompanying drawings. FIGS. 1 to 48 represent non-limiting, example embodiments as described herein. The above and other aspects, features, and advantages of certain embodiments of the disclosure will be more apparent from the following description taken in conjunction with the accompanying drawings, in which:

FIGS. 1 to 31 illustrate a method of manufacturing a semiconductor package in accordance with embodiments;

FIG. 32 is a cross-sectional view illustrating a method of manufacturing a semiconductor package in accordance with example embodiments;

FIGS. 33 to 47 are cross-sectional views illustrating a method of manufacturing a semiconductor package in accordance with example embodiments; and

FIG. 48 is a cross-sectional view illustrating a semiconductor package in accordance with example embodiments.

### DETAILED DESCRIPTION

Hereinafter, example embodiments will be explained in detail with reference to the accompanying drawings. The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the present disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the present disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’. In addition, hereinafter, ‘A’ to ‘B’ means at least one of elements from A (including A) and to B (including B).

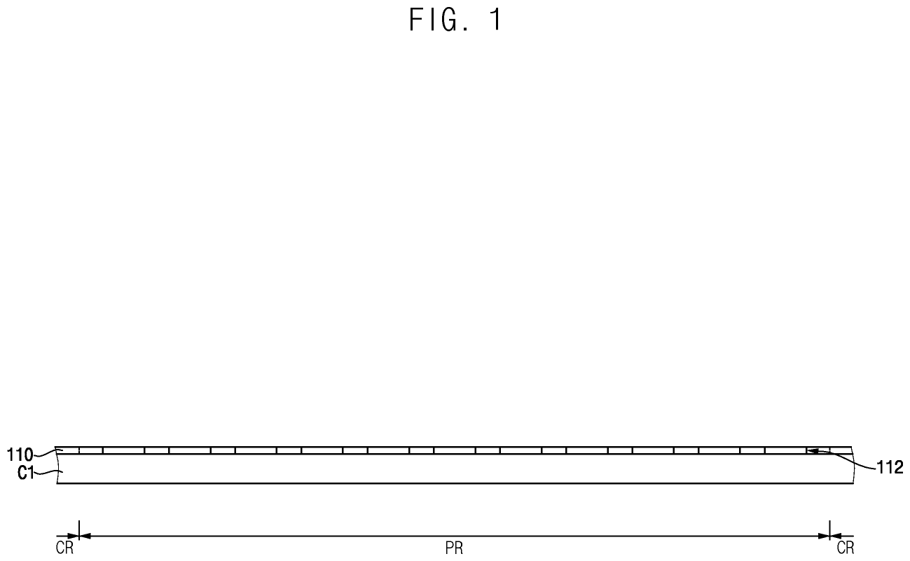

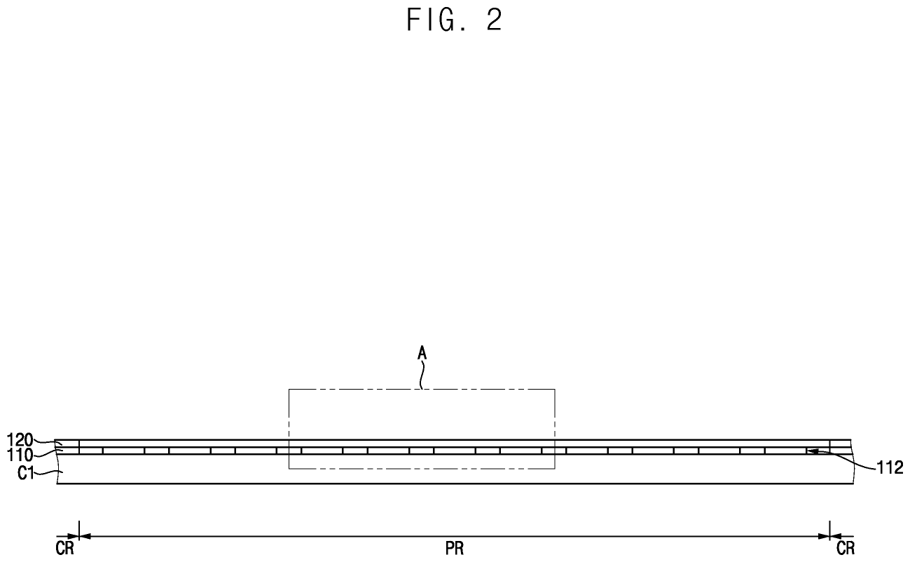

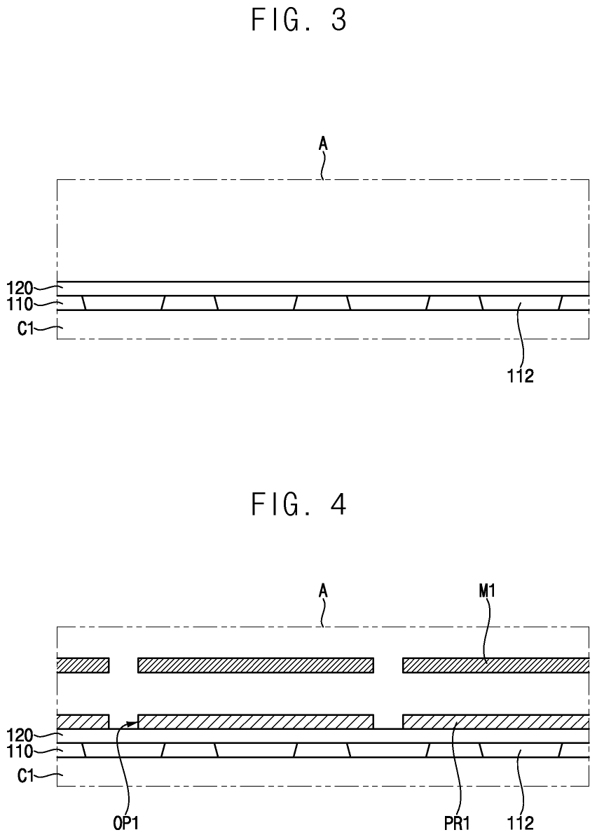

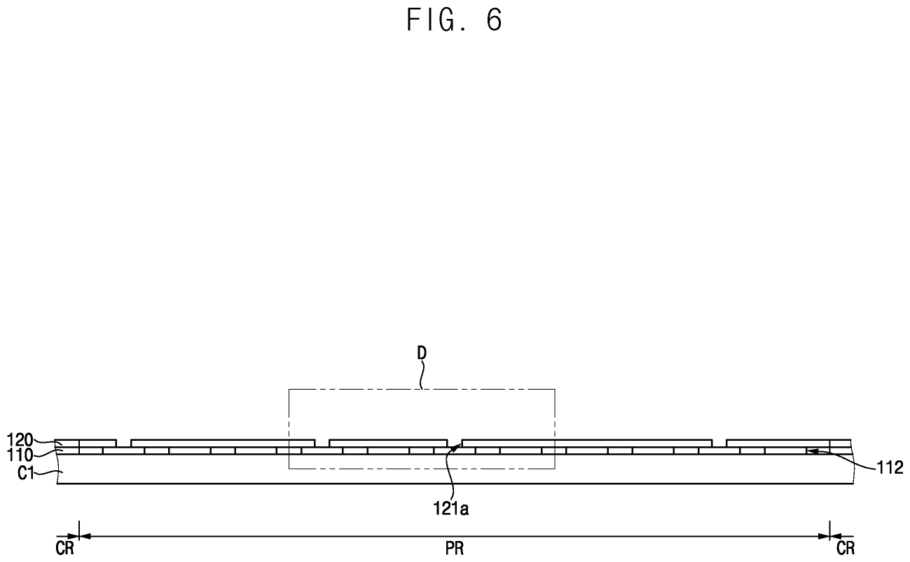

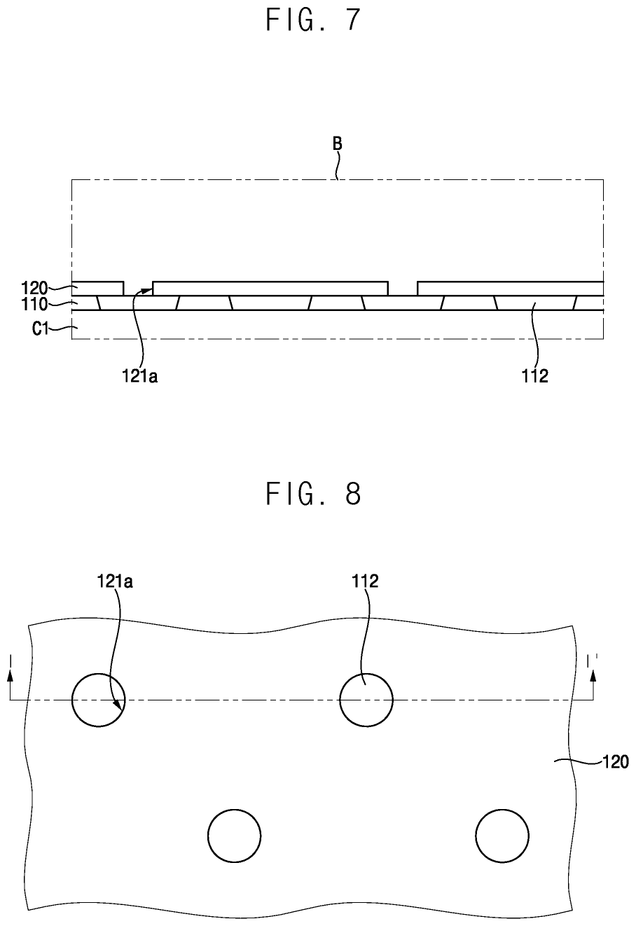

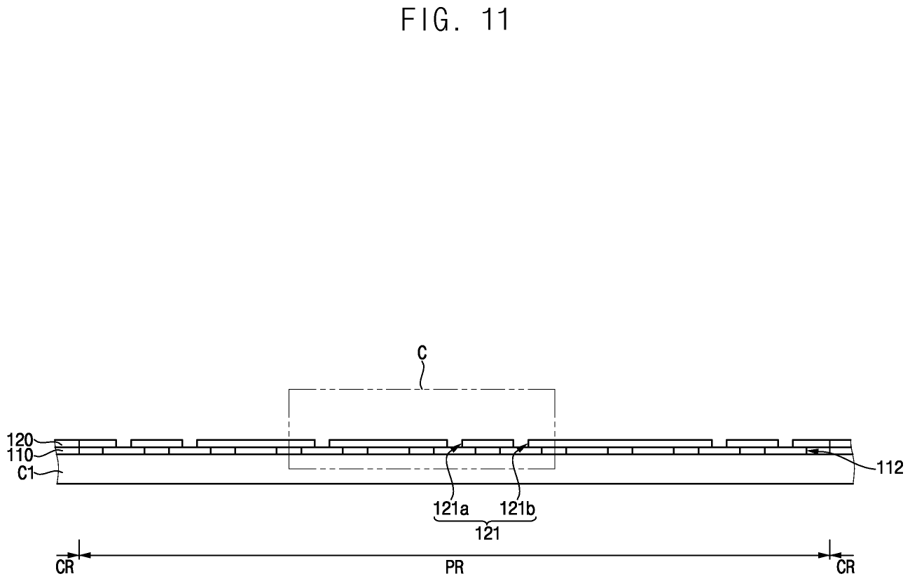

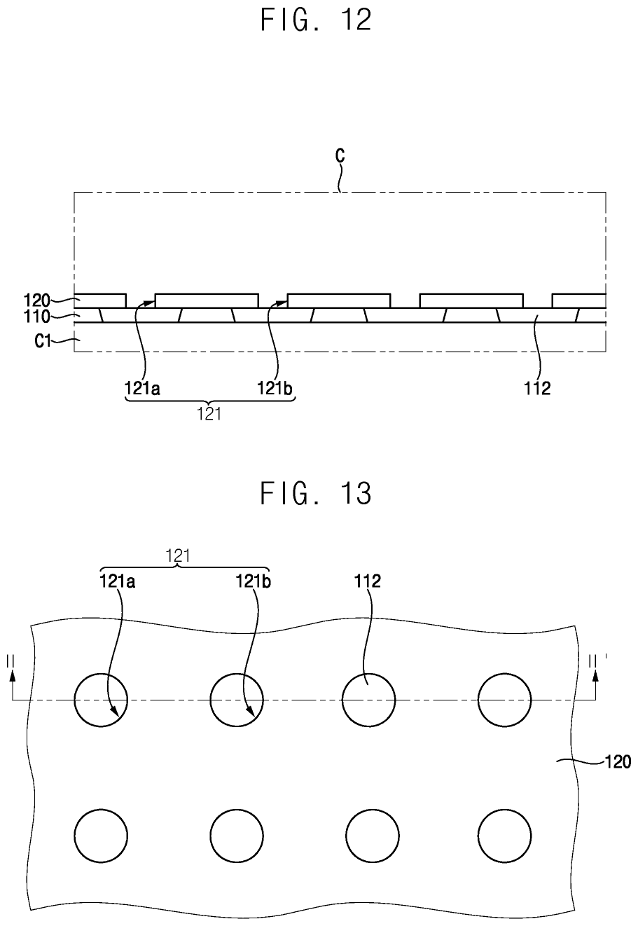

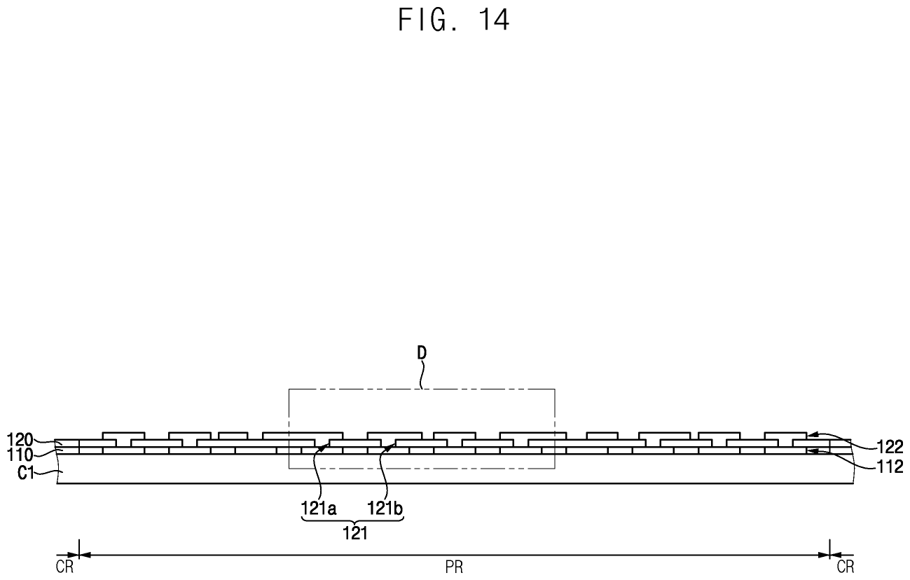

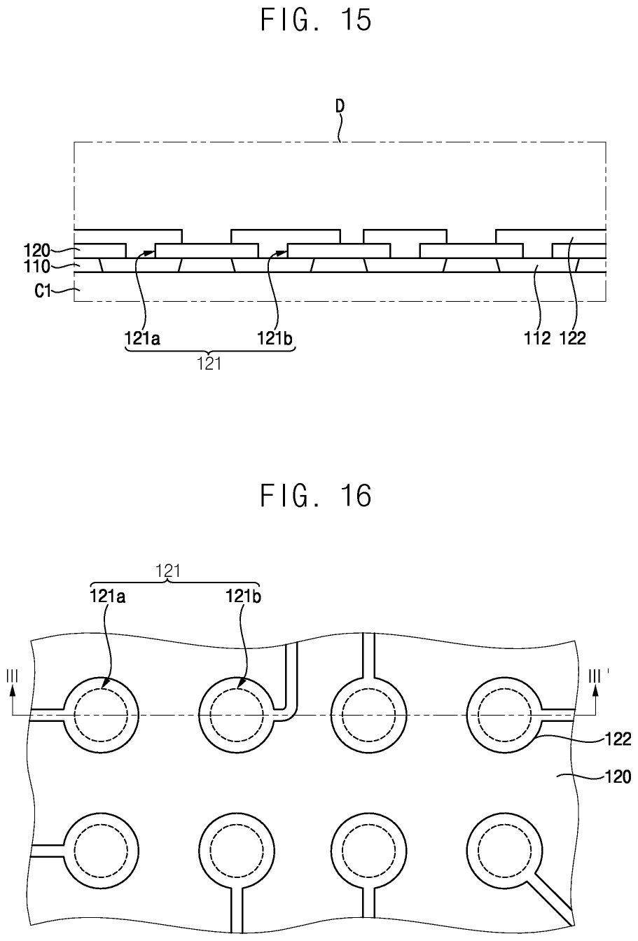

FIGS. 1 to 31 are views illustrating a method of manufacturing a semiconductor package in accordance with embodiments. FIGS. 1, 2, 6, 11, 14, and 17 to 31 are cross-sectional views illustrating a method of manufacturing a semiconductor package in accordance with embodiments. FIGS. 3 to 5 are enlarged cross-sectional views illustrating portion ‘A’ in FIG. 2. FIGS. 7, 9 and 10 are enlarged cross-sectional views illustrating portion ‘B’ in FIG. 6. FIG. 12 is an enlarged cross-sectional view illustrating a portion ‘C’ in FIG. 11. FIG. 13 is a plan view of FIG. 12. FIG. 15 is an enlarged cross-sectional view illustrating portion ‘D’ in FIG. 14. FIG. 16 is a plan view in FIG. 15. FIG. 7 is a cross-sectional view taken along the line I-I′ in FIG. 8. FIG. 12 is a cross-sectional view taken along the line II-II′ in FIG. 13. FIG. 15 is a cross-sectional view taken along the line III-III′ in FIG. 16.

Referring to FIGS. 1 to 22, a lower redistribution wiring layer 100 having first redistribution wirings 102 may be formed on a carrier substrate C1.

In example embodiments, the carrier substrate C1 may include a wafer substrate as a base substrate on which a plurality of semiconductor chips is disposed on the lower redistribution wiring layer and a sealing member is formed to cover them. The carrier substrate C1 may have a shape corresponding to a shape of a wafer where a semiconductor process is performed. For example, the carrier substrate C1 may include a silicon substrate, a glass substrate, a non-metal or metal plate, etc.

The carrier substrate C1 may include a package region PR on which the semiconductor chip is mounted and a cutting region CR surrounding the package region PR. As will be described later, the lower redistribution wiring layer 100 and the sealing member formed on the carrier substrate C1 may be cut along the cutting region CR that divides the plurality of package regions MR to be individualized.

As illustrated in FIG. 1, a plating process may be performed on the carrier substrate C1 to form a first lower insulating layer 110 including first bonding pads 112 formed therein. In an embodiment, a release film, a barrier metal layer, a seed layer, and the first lower insulating layer may be sequentially formed on the carrier substrate C1, and the first lower insulating layer may be patterned to form an opening that exposes a first bonding pad region. Then, the plating process may be performed on the seed layer to form the first bonding pad 112 in the opening.

For example, the first lower insulating layer 110 may include a polymer, a dielectric layer, etc. The first lower insulating layer 110 may include a photosensitive insulating material (PID) or an insulating film such as ABF. The first lower insulating layer may be formed by a spin coating process, a vapor deposition process, etc.

When the first lower insulating layer includes the photosensitive insulating material such as PID, a barrier metal layer, a seed layer, and the photosensitive insulating layer may be formed on the carrier substrate C1, and then the photosensitive insulating layer may be patterned to form a preliminary opening the exposes the first bonding pad region. The photosensitive insulating layer may be patterning by performing an exposure process and a development process. Subsequently, a curing process of the photosensitive insulating layer may be performed, such that a portion of the photosensitive insulating layer flows down toward the preliminary opening to form a tapered opening. Then, the first bonding pad may be formed in the opening of the photosensitive insulating layer by performing a plating process.

In this case, the first bonding pad may have a shape corresponding to the tapered opening. A diameter of a lower surface of the first bonding pad may be greater than a diameter of an upper surface of the first bonding pad. A sidewall of the opening of the first lower insulating layer may have a first angle with respect to a lower surface of the photosensitive insulating layer. The first angle may be within an obtuse angle range of 100 to 135 degrees. Accordingly, the sidewall of the first bonding pad may be inclined to have an acute angle of 45 to 80 degrees with respect to the lower surface of the photosensitive insulating layer.

The first bonding pad 112 may be a bump pad. The bump pad may include a solder pad or a pillar pad. For example, the first bonding pad may contain copper (Cu), aluminum (Al), tin (Sn), nickel (Ni), gold (Au), platinum (Pt), or an alloy thereof.

Referring to FIGS. 2 to 13, a second lower insulating layer 120 may be formed on the first lower insulating layer 110 to cover the first bonding pads 112, and the second lower insulating layer 120 may be patterned to form first openings 121 that expose at least portions of the first bonding pads 112.

First, as illustrated in FIGS. 2 and 3, the second lower insulating layer 120 may be formed on the first lower insulating layer 110 to cover the first bonding pads 112. For example, the second lower insulating layer 120 may include a polymer, a dielectric layer, etc. The second lower insulating layer 120 may include a photosensitive insulating material (PID) or an insulating film such as ABF. The second lower insulating layer may be formed by a spin coating process, a vapor deposition process, etc.

When the second lower insulating layer includes a photosensitive insulating material, a photosensitive insulating material layer may be formed on the first lower insulating layer 110 by a spin coating process, and a curing process may be performed on the photosensitive insulating material layer. The photosensitive insulating material layer may be changed into an insulating material layer by the curing process. The insulating material layer may include an insulating material having a low dielectric constant. Thus, the second lower insulating layer on which the curing process has been performed may lose a photoresist property that reacts to light.

Then, referring to FIGS. 4 to 8, a first photo etching process may be performed on the second lower insulating layer 120 to form first via holes 121a.

As illustrated in FIG. 4, a first photoresist layer may be formed on the second lower insulating layer 120, an exposure process using a first exposure mask M1 may be performed on the first photoresist layer, and a development process may be performed to form a first photoresist pattern PR1 having first opening patterns OP1 that expose first via regions.

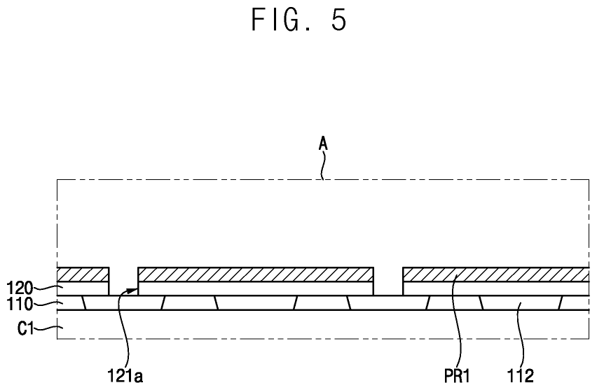

As illustrated in FIG. 5, the second lower insulating layer 120 may be etched using the first photoresist pattern PR1 as an etching mask to form the first via holes 121a. The first via holes 121a may be etched by an isotropic etching process. The isotropic etching process may include a wet etching process or a dry etching process. A sidewall of the first via hole 121a formed by the isotropic etching process may have an angle close to a right angle with respect to a lower surface of the second lower insulating layer, for example, an angle range of 85 to 105 degrees.

As illustrated in FIGS. 6 to 8, the first photoresist pattern PR1 may be removed from the second lower insulating layer 120 by an ashing process and a strip process. The first via holes 121a may expose only first portions of the first bonding pads 112 under the second lower insulating layer 120.

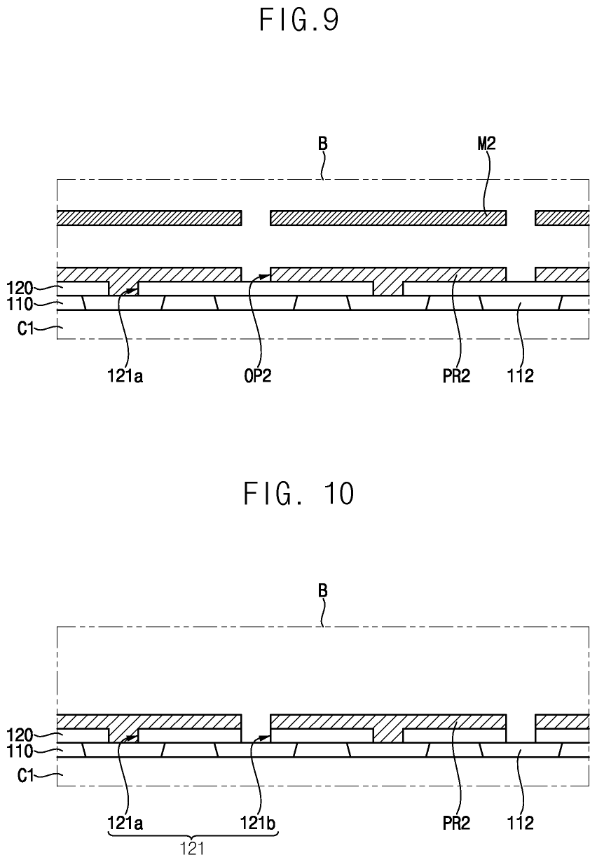

Then, referring to FIGS. 9 to 13, a second photo etching process may be performed on the second lower insulating layer 120 to form second via holes 121b.

As illustrated in FIG. 9, a second photoresist layer may be formed on the second lower insulating layer 120, an exposure process using a second exposure mask M2 may be performed on the second photoresist layer may be exposed, and a development process may be performed to form a second photoresist pattern PR2 having second opening patterns OP2 that expose second via regions.

As illustrated in FIG. 10, the second lower insulating layer 120 may be etched using the second photoresist pattern PR2 as an etching mask to form the second via holes 121b. The second via holes 121b may be etched by an isotropic etching process. The isotropic etching process may include a wet etching process or a dry etching process. A sidewall of the second via hole 121b formed by the isotropic etching process may have an angle close to a right angle with respect to the lower surface of the second lower insulating layer, for example, an angle range of 80 to 110 degrees.

As illustrated in FIGS. 11 to 13, the second photoresist pattern PR2 may be removed from the second lower insulating layer 120 by an ashing process and a strip process. The second via holes 121b may expose only second portions of the first bonding pads 112 under the second lower insulating layer 120. Thus, first openings 121 including the first via holes 121a and the second via holes 121b may be formed in the second lower insulating layer 120.

The first via holes 121a and the second via holes 121b may be alternately arranged in one direction. The first via holes 121a and the second via holes 121b may be formed through a double patterning process including two etching processes. For example, at least one of the first via hole 121a and the second via hole 121b may have a diameter of 1 μm to 8 μm. The first via hole 121a and the second via hole 121b may have the same diameter. Alternatively, the diameter of the first via hole 121a may be greater than or less than the diameter of the second via hole 121b.

The first openings 121 may be formed into the first via holes 121a and the second via holes 121b by the first photo etching process and the second photo etching process different from each other, to thereby form the first openings 121 having fine diameters and pitches. Accordingly, it may be possible to overcome the limitation of the resolution of the PID insulating layer lower than the resolution of the conventional photoresist pattern.

Referring to FIGS. 14 to 16, first lower redistribution wirings 122 may be formed on the second lower insulating layer 120. The first lower redistribution wiring 122 may be electrically connected to the first bonding pads 112 through the first openings 121 of the second lower insulating layer 120.

In example embodiments, a barrier layer and a seed layer may be sequentially formed on the second lower insulating layer 120. The barrier layer may be formed on a sidewall of the first opening 121 of the second lower insulating layer 120 and a portion of the first bonding pad 112 exposed by the first opening 121.

For example, the barrier layer may include titanium, titanium nitride, tantalum, tantalum nitride, tungsten, etc. The seed layer may include copper, gold, silver, aluminum, or an alloy thereof. The barrier layer and the seed layer may be formed by a physical deposition method, etc. The barrier layer may have a thickness of about 500 Å to about 2,000 Å. The seed layer may have a thickness of about 500 Å to about 1,500 Å.

Then, a photoresist layer may be formed on the seed layer, and an exposure process and development process may be performed on the photoresist layer to form a photoresist pattern having openings that expose first lower redistribution wiring regions. A first plating pattern may be formed in the openings of the photoresist pattern, and the photoresist pattern may be removed from the second lower insulating layer 120. The first plating pattern may be formed by an electroplating process or an electroless plating process. For example, the plating pattern may have a thickness of 2 μm to 10 μm.

Then, a portion of the seed layer exposed by the first plating pattern may be removed to form a first seed layer pattern. portion of the seed layer exposed by the first plating pattern may be removed by an isotropic etching process. The portion of the seed layer may be removed by a wet etching process.

Then, a portion of the barrier layer exposed by the first seed layer pattern may be removed to form a first barrier layer pattern. The portion of the barrier layer exposed by the first plating pattern may be removed by an anisotropic etching process. The portion of the barrier layer may be removed by a dry etching process.

Thus, the first lower redistribution wiring 122 including the first barrier layer pattern, the first seed layer pattern and the first plating pattern may be formed on the second lower insulating layer 120. The first lower redistribution wiring 122 may include a first redistribution via, a first redistribution line, and a first redistribution pad. The first redistribution via may be formed in the first openings 121 of the second lower insulating layer 120. The first redistribution line may extend on the second lower insulating layer. The first redistribution pad may be provided in a portion of the first redistribution line.

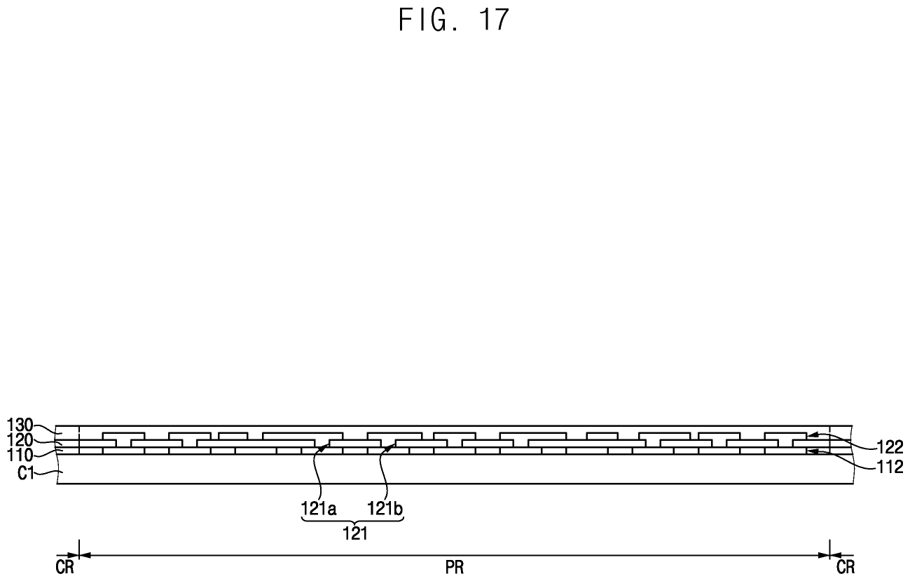

Referring to FIGS. 17 to 19, processes the same as or similar to the processes described with reference to FIGS. 2 to 13 may be performed to form a third lower insulating layer 130 covering the first lower redistribution wirings 122, and the third lower insulating layer 130 may be patterned to form second openings 131 exposing at least portions of the first lower redistribution wirings 122 may be formed by.

As illustrated in FIG. 17, the third lower insulating layer 130 may be formed on the second lower insulating layer 120 to cover the first lower redistribution wirings 122. For example, the third lower insulating layer 130 may include a polymer, a dielectric layer, etc. The third lower insulating layer 130 may include a photosensitive insulating material (PID) or an insulating film such as ABF. The third lower insulating layer may be formed by a spin coating process, a vapor deposition process, etc.

When the third lower insulating layer includes a photosensitive insulating material, a photosensitive insulating material layer may be formed on the second lower insulating layer 120 by a spin coating process, and a curing process may be performed on the photosensitive insulating material layer. The photosensitive insulating material layer may be changed into an insulating material layer by the curing process. The insulating material layer may include an insulating material having a low dielectric constant. Thus, the third lower insulating layer on which the curing process has been performed may lose a photoresist property that reacts to light.

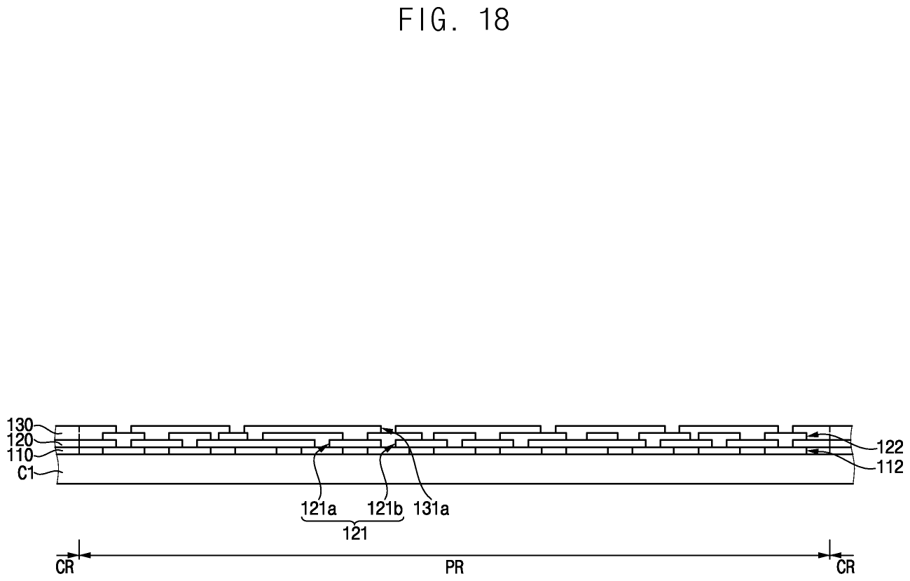

As illustrated in FIG. 18, a third photo etching process may be performed on the third lower insulating layer 130 to form third via holes 131a. A third photoresist layer may be formed on the third lower insulation layer 130, an exposure process using a third exposure mask may be performed on the third photoresist layer, and a development process may be performed to form a third photoresist pattern having third opening patterns that expose third via regions. The third lower insulating layer 130 may be etched using the third photoresist pattern as an etching mask to form the third via holes 131a. The third via holes 131a may be etched by an isotropic etching process. Then, the third photoresist pattern may be removed from the third lower insulating layer 130 by an ashing process and a strip process. The third via holes 131a may expose only first portions of the first lower redistribution wirings 122 under the third lower insulating layer 130.

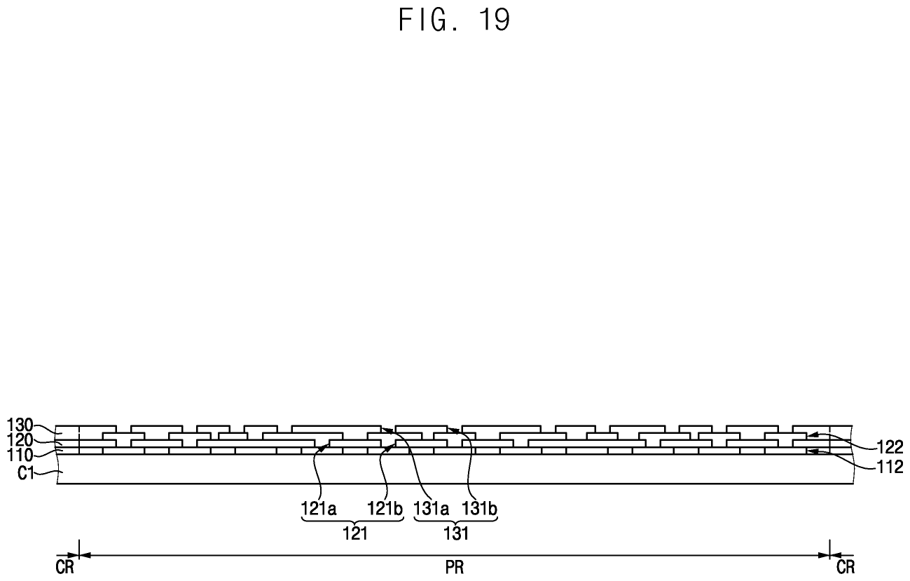

As illustrated in FIG. 19, a fourth photo etching process may be performed on the third lower insulating layer 130 to form fourth via holes 131b. A fourth photoresist layer may be formed on the third lower insulating layer 130, an exposure process using a fourth exposure mask may be performed on the fourth photoresist layer, and a development process may be performed to form fourth opening patterns that expose fourth via regions. the third lower insulating layer 130 may be etched using the fourth photoresist pattern as an etching mask to form the fourth via holes 131b. The fourth via holes 131b may be etched by an isotropic etching process. The fourth via holes 131b may expose only second portions of the first lower redistribution wiring 122 under the third lower insulating layer 130. Thus, the second openings 131 including the third via holes 131a and the fourth via holes 131b may be formed in the third lower insulating layer 130.

The third via holes 131a and the fourth via holes 131b may be alternately arranged in one direction. The third via holes 131a and the fourth via holes 131b may be formed through a double patterning process including two etching processes. For example, at least one of the third via hole 131a and the fourth via hole 131b may have a diameter of 1 μm to 8 μm. The third via hole 131a and the fourth via hole 131b may have the same diameter. Alternatively, the diameter of the third via hole 131a may be greater than or less than the diameter of the fourth via hole 131b.

The second openings 131 with fine diameters and pitches may be formed by forming the third via holes 131a and the fourth via holes 131b by the first photo etching process and the second photo etching process different from each other. Accordingly, it may be possible to overcome the limitation of the resolution of the PID insulating layer lower than the resolution of the conventional photoresist pattern.

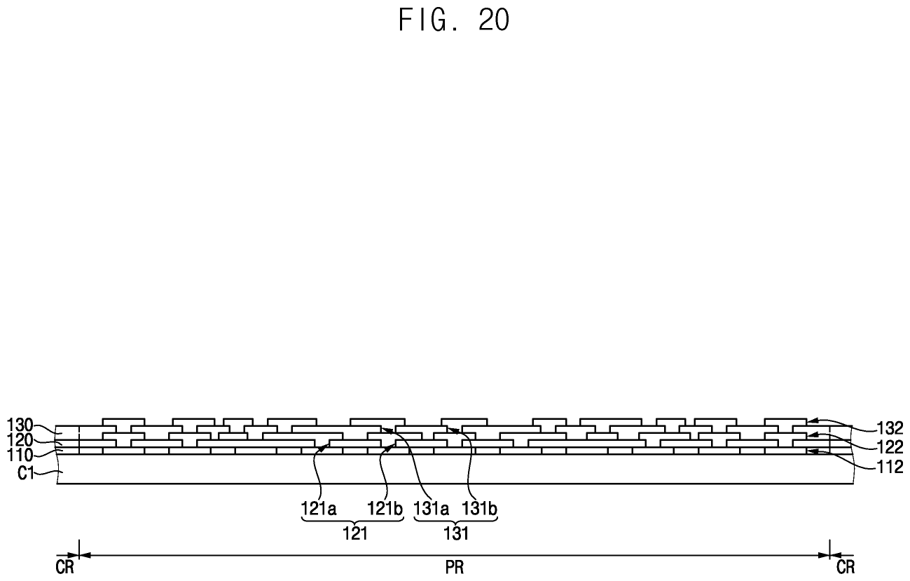

Referring to FIG. 20, processes the same as or similar to the processes described with reference to FIGS. 14 to 16 may be performed to form second lower redistribution wirings 132 on the third lower insulating layer 130.

For example, a barrier layer and a seed layer may be sequentially formed on the third lower insulating layer 130 and a photoresist pattern having openings that expose second lower redistribution wiring regions may be formed on the seed layer. Subsequently, a second plating pattern may be formed in the openings of the photoresist pattern by a plating process, and the photoresist pattern may be removed from the third lower insulating layer 130.

Then, a portion of the seed layer exposed by the second plating pattern may be removed to form a second seed layer pattern, and a portion of the barrier layer exposed by the second seed layer pattern may be removed to form a second barrier layer pattern.

Thus, the second lower redistribution wiring 132 including the second barrier layer pattern, the second seed layer pattern, and the second plating pattern may be formed on the third lower insulating layer 130. The second lower redistribution wirings 132 may be electrically connected to the first lower redistribution wirings 122 through the second openings 131 of the third lower insulating layer 130.

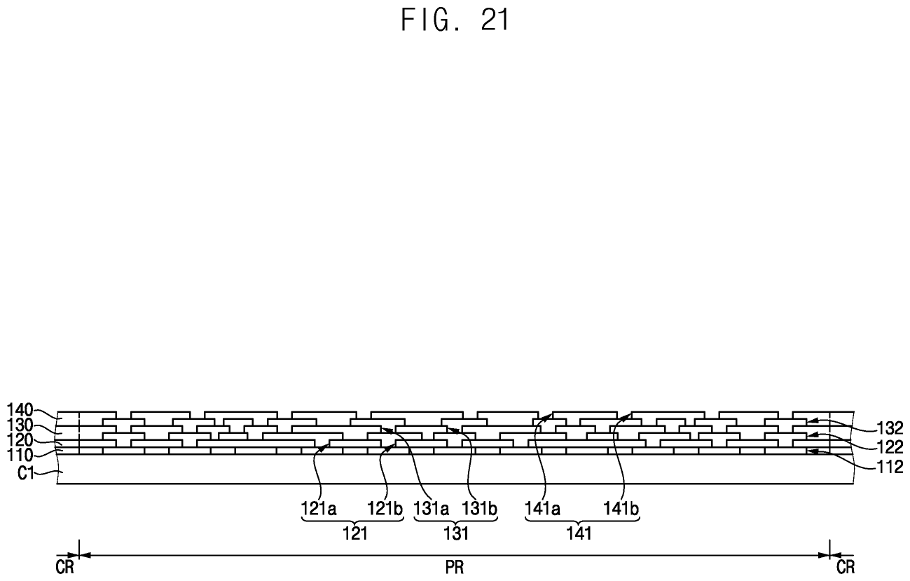

Referring to FIG. 21, processes the same as or similar to the processes described with reference to FIGS. 2 to 13 may be performed to form a fourth lower insulating layer 140 covering the second lower redistribution wirings 132 on the third lower insulating layer 130, and the fourth lower insulating layer 140 may be patterned to form third openings 141 exposing at least portions of the second lower redistribution wirings 132. The third openings 141 including fifth via holes 141a and fifth via holes 141b may be formed in the fourth lower insulating layer 140.

The fifth via holes 141a and the sixth via holes 141b may be alternately arranged in one direction. The fifth via holes 141a and the sixth via holes 141b may be formed through a double patterning process including two etching processes. The third openings 141 with fine diameters and pitches may be formed by forming the third openings 141 into the fifth via holes 141a and the fourth via holes 141b by the first photo etching process and the second photo etching process.

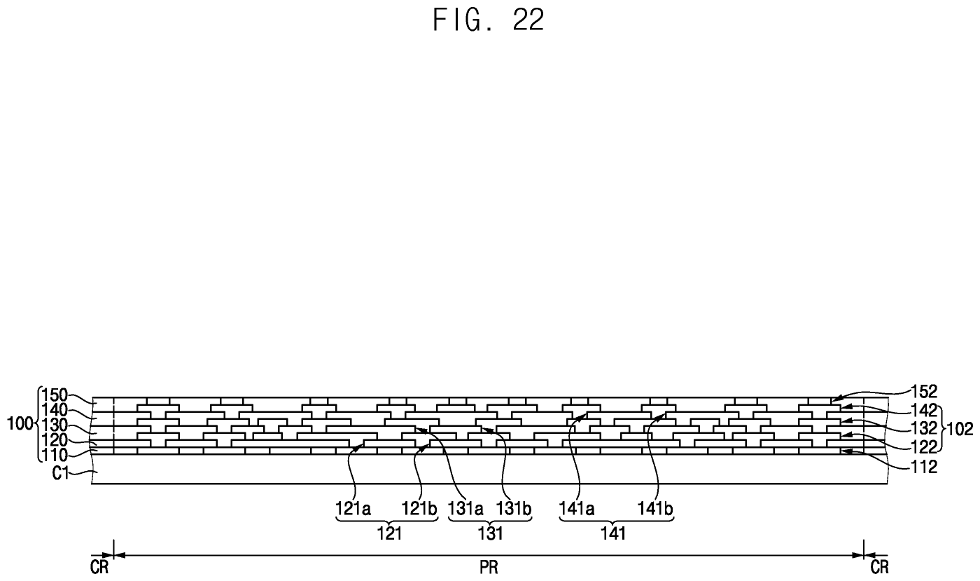

Referring to FIG. 22, processes the same as or similar to the processes described with reference to FIGS. 14 to 16 may be performed to form third lower redistribution wirings 142 on the fourth lower insulating layer 140. Subsequently, second bonding pads 152 may be formed on the third lower redistribution wiring 142.

For example, a barrier layer and a seed layer may be sequentially formed on the fourth lower insulating layer 140 and a photoresist pattern having openings that expose third lower redistribution regions may be formed on the seed layer. Subsequently, a third plating pattern may be formed in the openings of the photoresist pattern by a plating process, and the photoresist pattern may be removed from the third lower insulating layer 130.

Then, a portion of the seed layer exposed by the third plating pattern may be removed to form a third seed layer pattern, and a portion of the barrier layer exposed by the third seed layer pattern may be removed to form a third barrier layer pattern.

Thus, a third lower redistribution wiring 142 including the third barrier layer pattern, the third seed layer pattern, and the third plating pattern may be formed on the fourth lower insulating layer 140. The third lower redistribution wirings 142 may be electrically connected to the second lower redistribution wirings 132 through the third openings 141 of the fourth lower insulating layer 140.

Then, processes similar to the processes described with reference to FIGS. 14 to 16 may be performed to form the second bonding pads 152 on the third lower redistribution wiring 142.

The second bonding pad 152 including a fourth barrier layer pattern, a fourth seed layer pattern, and a fourth plating pattern may be formed on the third lower redistribution wiring 142.

Then, a solder resist layer 150 as a fifth lower insulating layer may be formed on the fourth lower insulating layer 140 to cover the third lower redistribution wiring 142 and to exposes at least a portion of the second bonding pad 152.

Thus, the lower redistribution wiring layer 100 having the first to fifth lower insulating layers 110, 120, 130, 140, 150 may be formed. The lower redistribution wiring layer 100 may be a front re-distribution layer (FRDL) of a fan-out package. The second bonding pads 152 may be exposed from an upper surface of the lower redistribution wiring layer 100.

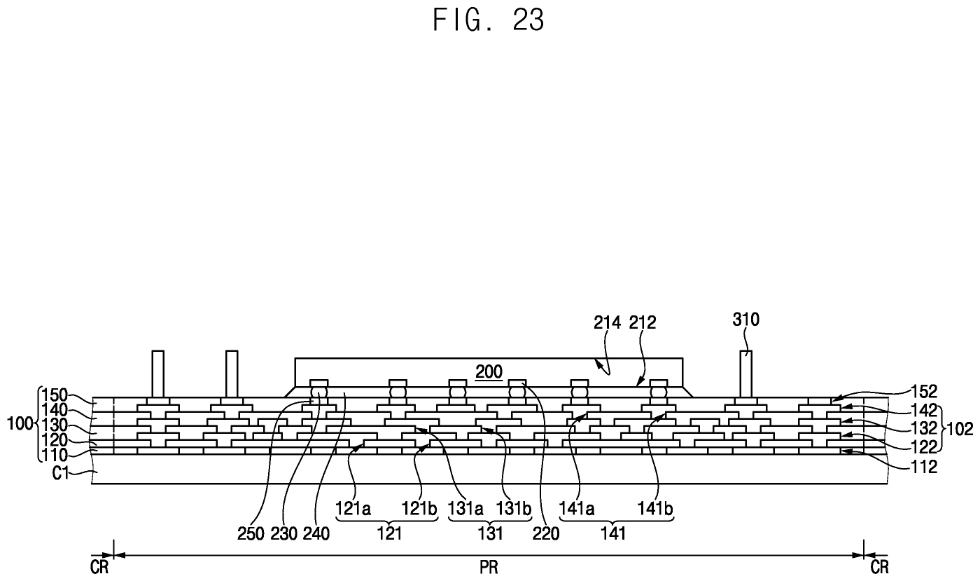

Referring to FIG. 23, a plurality of through-vias 310 as conductive connection structures may be formed on the upper surface of the lower redistribution wiring layer 100, and at least one semiconductor chip 200 may be mounted on the upper surface of the lower redistribution wiring layer 100.

In example embodiments, a photoresist layer may be formed on the upper surface of the lower redistribution wiring layer 100, and an exposure process may be performed on the photoresist layer to form a photoresist pattern having openings for forming a plurality of through-vias in a fan-out region of the lower redistribution wiring layer 100. The opening may expose at least a portion of the second bonding pad 152 in the fan-out region.

Then, an electroplating process may be performed to fill the openings of the photoresist pattern with a conductive material to form the through-vias 310. Then, the photoresist pattern may be removed by a strip process.

The through-vias 310 as the conductive connection structure may extend upward from the second bonding pads 152, respectively. The through-vias 310 may be electrically connected to the first redistribution wirings 102. As will be described later, the through via 310 may be provided to penetrate the sealing member to serve as an electrical connection passage. That is, the through-vias 310 may be provided in a fan-out region outside the region where the semiconductor chip die is disposed to be used for electrical connection.

Then, the at least one semiconductor chip 200 may be mounted in a fan-in region of the lower redistribution wiring layer 100.

In example embodiments, the semiconductor chip 200 may be mounted on the upper surface of the lower redistribution wiring layer 100 by a flip chip bonding method. The semiconductor chip 200 may be disposed such that a front surface 212 on which chip pads 220 are formed, that is, an active surface faces the lower redistribution wiring layer 100. The chip pads 220 of the semiconductor chip 200 may be electrically connected to the second bonding pads 152 of the lower redistribution wiring layer 100 by conductive bumps 230. Thus, the semiconductor chip 200 may be electrically connected to the first redistribution wirings 102 of the lower redistribution wiring layer 100 by the conductive bumps 230. For example, the conductive bump 230 may include a micro bump (uBump).

An underfill member 240 may be underfilled between the semiconductor chip 200 and the lower redistribution wiring layer 100. The underfill member may include a material with relatively high fluidity to effectively fill a small space between the semiconductor chip and the lower redistribution wiring layer. For example, the underfill member may include an adhesive including an epoxy material.

The semiconductor chip may be a logic chip including a logic circuit. The logic chip may be a controller that controls memory chips. The semiconductor chip may be a processor chip such as an ASIC, an application processor (AP) as a host such as CPU, GPU, or SOC.

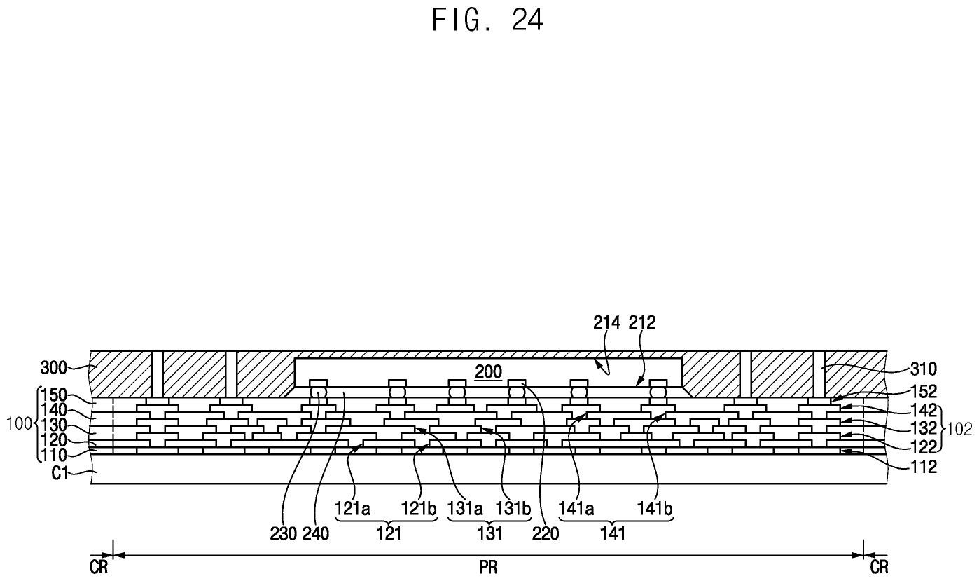

Referring to FIG. 24, a sealing member 300 may be formed on the upper surface of the lower redistribution wiring layer 100 to cover the semiconductor chip 200 and the plurality of through-vias 310.

The sealing member 300 may be formed to cover an upper surface 214 of the semiconductor chip 200. The sealing member 300 may expose upper surfaces of the plurality of through-vias 310. For example, the sealing member 300 may include an epoxy mold composite (EMC). The sealing member 300 may include UV resin, polyurethane resin, silicon resin, silica filler, etc.

The sealing member 300 may include a first molding portion covering the upper surface 214 of the semiconductor chip 200 and a second molding portion covering the upper surface of the lower redistribution wiring layer 100 around the semiconductor chip 200.

Thus, the plurality of through-vias 310 may be formed on the upper surface of the fan-out region of the lower redistribution wiring layer 100 and may extend to penetrate the sealing member 300. The through via 310 may be a through mold via (TMV) formed through the second molding portion of the sealing member 300.

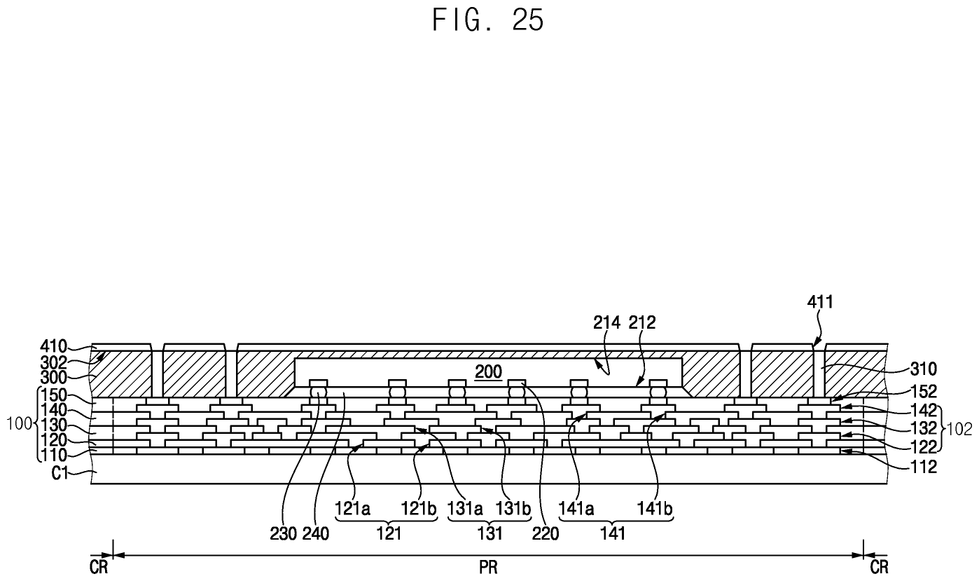

Referring to FIGS. 25 to 30, an upper redistribution wiring layer 400 having second redistribution wirings 402 electrically connected to the through-vias 310 may be formed on the upper surface 302 of the sealing member 300.

As illustrated in FIG. 25, a first upper insulating layer 410 may be formed on the upper surface 302 of the sealing member 300, and then the first upper insulating layer 410 may be patterned to form fourth openings 411 that expose the through-vias 310. The fourth openings 411 of the patterned first upper insulating layer 410 may expose upper surfaces of the through-vias 310, respectively.

The fourth openings 411 in the first upper insulating layer 410 may be formed by performing processes the same as or similar to the processes described with reference to FIGS. 2 to 13. In this case, the first upper insulating layer 410 may include PID, and the fourth openings 411 may include seventh via holes and eighth via holes. The seventh via holes and the eighth via holes may be formed through a double patterning process including two etching processes.

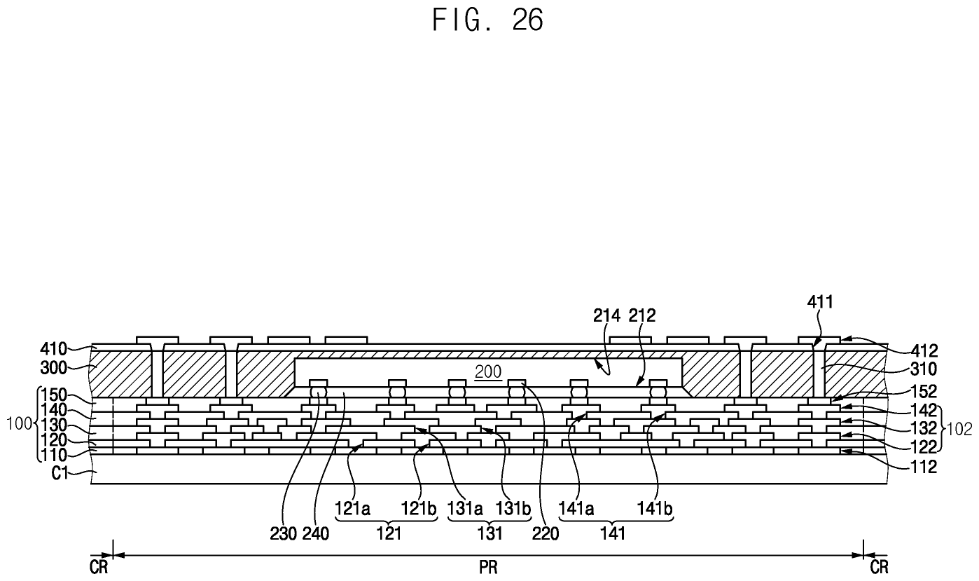

As illustrated in FIG. 26, after forming a seed layer on exposed portions of the through-vias 310 and in the fourth openings, the seed layer may be patterned and electroplated to form first upper redistribution wirings 412. Thus, at least portions of the first upper redistribution wirings 412 may be electrically connected to the through-vias 310 through the fourth openings.

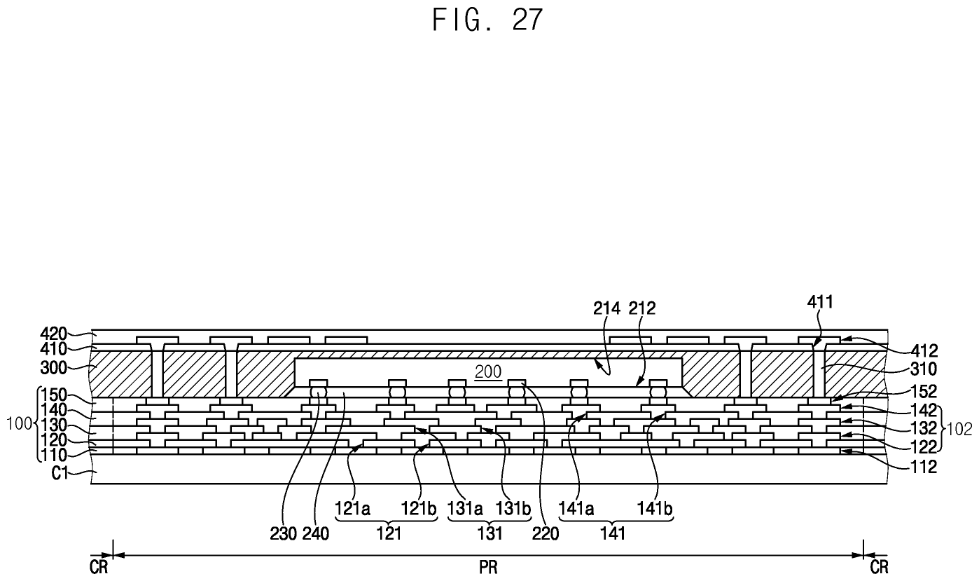

As illustrated in FIG. 27, a second upper insulating layer 420 may be formed on the first upper insulating layer 410 to cover the first upper redistribution wirings 412. For example, the second upper insulating layer 420 may include a polymer, a dielectric layer, etc. The second upper insulating layer 420 may include a photosensitive insulating material (PID), an insulating film such as ABF, etc. The second upper insulating layer may be formed by a spin coating process, a vapor deposition process, etc.

When the second upper insulating layer includes a photosensitive insulating material, a photosensitive insulating material layer may be formed on the first upper insulating layer 410 by a spin coating process, and a curing process may be performed on the photosensitive insulating material layer. The photosensitive insulating material layer may be changed into an insulating material layer by the curing process. The insulating material layer may include an insulating material having a low dielectric constant. Thus, the second upper insulating layer on which the curing process has been performed may lose a photoresist property that reacts to light.

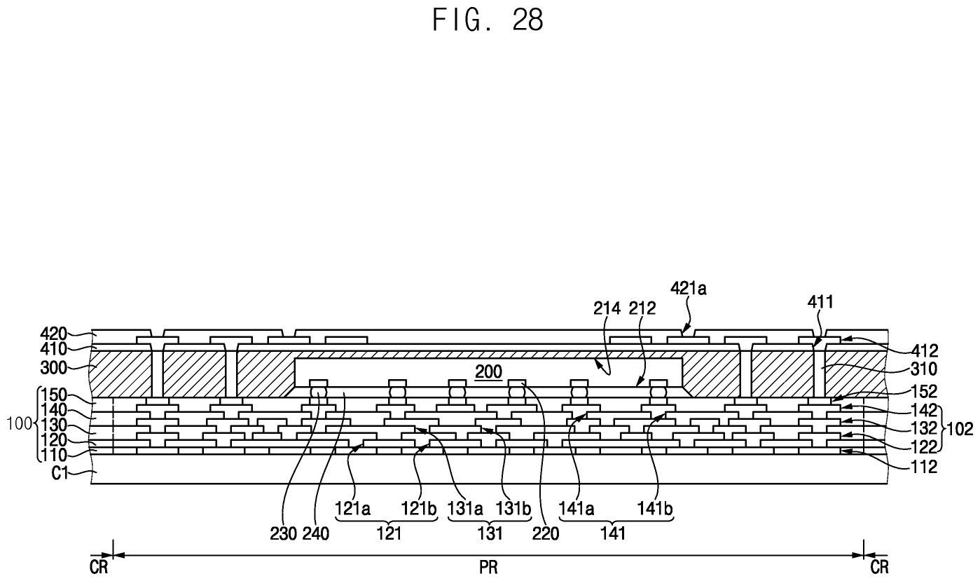

As illustrated in FIG. 28, ninth via holes 421a may be formed in the second upper insulating layer 420 by performing processes the same as or similar to the processes described with reference to FIGS. 4 to 8. A fifth photoresist pattern with fifth opening patterns may be formed on the second upper insulation layer 420, an exposure process using a fifth exposure mask may be performed on the fifth photoresist layer, and a development process may be performed to form a fifth photoresist pattern having the fifth opening patterns that expose ninth via regions. The second upper insulating layer 420 may be etched using the fifth photoresist pattern as an etching mask to form the ninth via holes 421a. The ninth via holes 421a may be etched by an isotropic etching process. Then, the fifth photoresist pattern may be removed from the second upper insulating layer 420 by an ashing process and a strip process. The ninth via holes 421a may expose only first portions of the first upper redistribution wirings 412 under the second upper insulating layer 420.

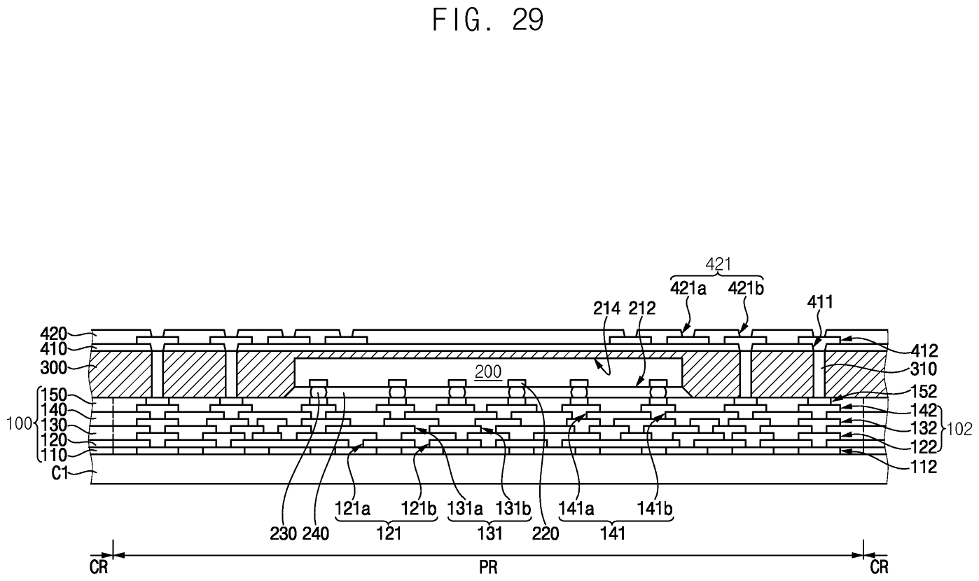

As illustrated in FIG. 29, tenth via holes 421b may be formed in the second upper insulating layer 420 by performing processes the same as or similar to the processes described with reference to FIGS. 9 to 13. A sixth photoresist pattern having sixth opening patterns may be formed on the second upper insulation layer 420, an exposure process using a sixth exposure mask may be performed on the sixth photoresist layer, and a development process may be performed to form a sixth photoresist pattern having sixth opening patterns that expose tenth via regions. The second upper insulating layer 420 may be etched using the sixth photoresist pattern as an etching mask to form the tenth via holes 421b. The tenth via holes 421b may be etched by an isotropic etching process. The tenth via holes 421b may expose only second portions of the first upper redistribution wiring 412 under the second upper insulating layer 420. Thus, fifth openings 421 including the ninth via holes 421a and the tenth via holes 421b may be formed in the second upper insulating layer 420.

The ninth via holes 421a and the tenth via holes 421b may be alternately arranged in one direction. The ninth via holes 421a and the tenth via holes 421b may be formed through a double patterning process including two etching processes. For example, at least one of the ninth via holes 421a and the tenth via holes 421b may have a diameter of 1 μm to 8 μm. The ninth via hole 421a and the tenth via hole 421b may have the same diameter. Alternatively, the diameter of the ninth via hole 421a may be greater than or less than the diameter of the tenth via hole 421b.

The fifth openings 421 having fine diameters and pitches may be formed by dividing the fifth openings 421 into ninth via holes 421a and tenth via holes 421b by the first photo etching process and the second photo etching process. Thus, the limitation of the resolution of the PID insulating layer lower than the resolution of the conventional photoresist pattern may be overcome.

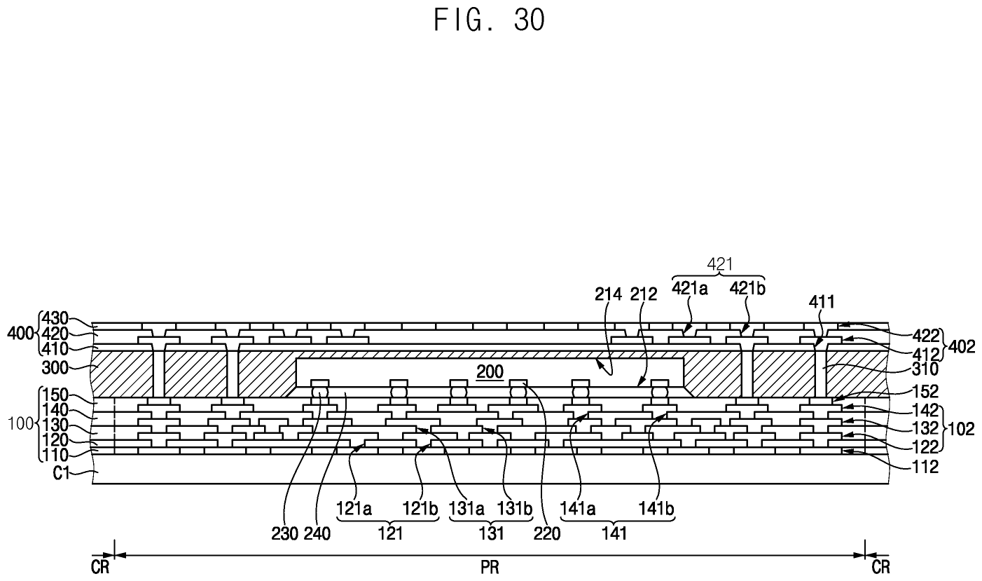

As illustrated in FIG. 30, processes the same as or similar to the processes described with reference to FIG. 26 may be performed to form second upper redistribution wirings 422 on the second upper insulating layer 420.

Thus, the second redistribution wirings 402 may include first upper redistribution wirings 412 and second upper redistribution wirings 422, which are stacked in at least two layers. In this case, the second upper redistribution wiring 422 may correspond to the uppermost redistribution wiring among the second redistribution wirings 402.

Then, upper bonding pads may be formed on the second upper redistribution wiring 422 as the uppermost redistribution wiring, and a third upper insulating layer 430 may be formed on the second upper insulating layer 420 to expose at least a portion of the upper bonding pad on the second upper redistribution wiring 422. The third upper insulating layer 430 may serve as a passivation layer.

Thus, the upper redistribution wiring layer 400 having the first upper insulating layer 310, the second upper insulating layer 320, and the third upper insulating layer 430 may be formed. The upper redistribution wiring layer 400 may be a backside redistribution wiring layer (BRDL) of the fan-out package. The upper bonding pads may be exposed from an upper surface of the upper redistribution wiring layer 400.

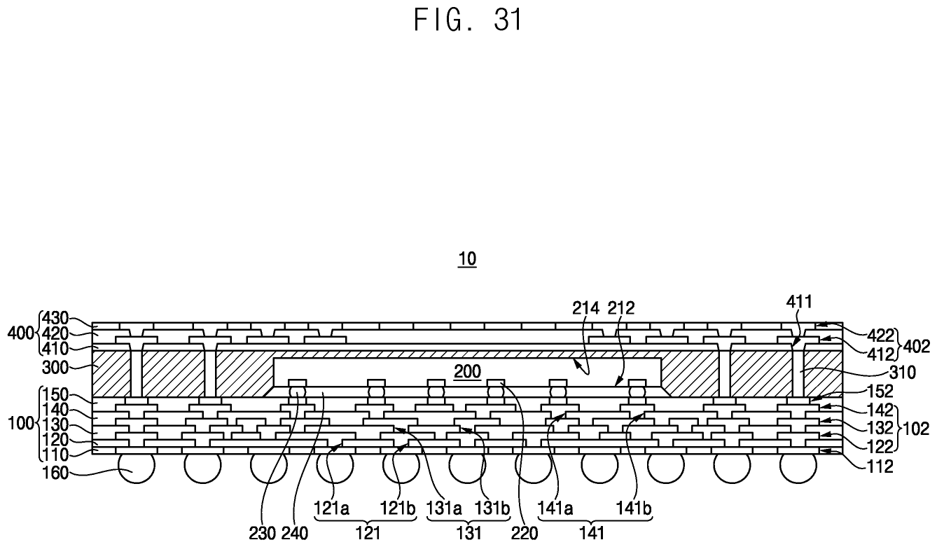

Referring to FIG. 31, external connection members 160 electrically connected to the first redistribution wirings 102 may be formed on the outer surface of the lower redistribution wiring layer 100, that is, on the lower surface.

Then, the lower redistribution wiring layer 100 may be individualized by a sawing process to complete a fan-out wafer level package 10 that includes the sealing member 300, the lower redistribution wiring layer 100 formed on the lower surface of the sealing member 300, and the upper redistribution wiring layer 400 formed on the upper surface of the sealing member 300.

In example embodiments, the semiconductor package 10 may be a fan-out package where the lower redistribution wiring layer 100 extends to the sealing member 300 covering the outer surface of the semiconductor chip 200. The lower redistribution wiring layer 100 may be formed by a wafer-level redistribution wiring process. In addition, the semiconductor package 10 may be provided as a unit package on which a second package is stacked.

In addition, the semiconductor package 10 may be provided as a system in package (SIP). For example, one or more semiconductor chips may be disposed on the lower redistribution wiring layer 100. The semiconductor chips may include a logic chip and/or a memory chip including a logic circuit. The logic chip may be a controller that controls memory chips. The memory chip may include various types of memory circuits such as DRAM, SRAM, flash, PRAM, ReRAM, FeRAM, or MRAM.

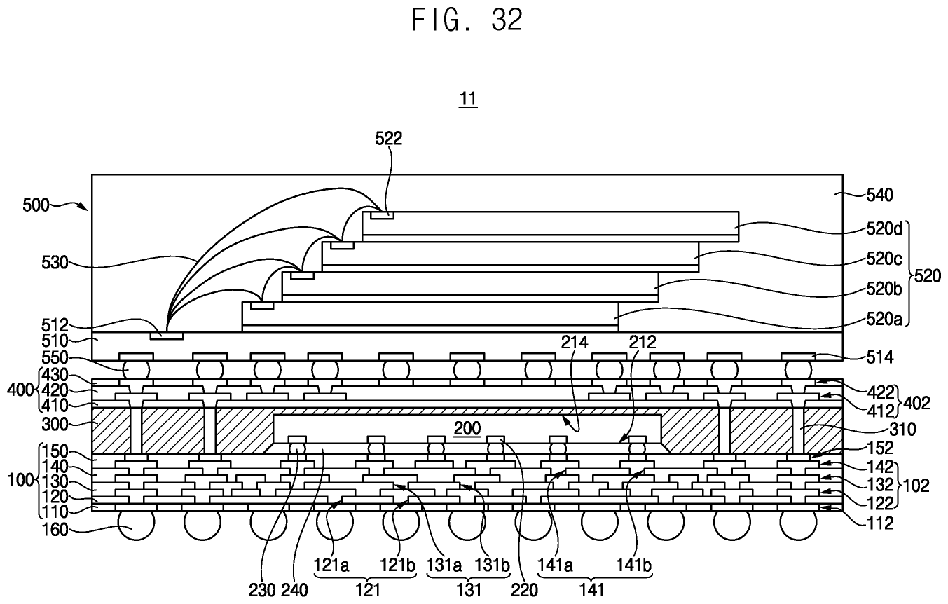

FIG. 32 is a cross-sectional view illustrating a method of manufacturing a semiconductor package in accordance with example embodiments. The semiconductor package is substantially the same as the semiconductor package described with reference to FIG. 31, except for an additional configuration of a second package. Thus, same reference numerals will be used to refer to the same or like elements and any further repetitive explanation concerning the above elements will be omitted.

Referring to FIG. 32, a semiconductor package 11 may be formed by stacking a second package 500 on a first package. The first package may include a lower redistribution wiring layer 100, a semiconductor chip 200, a sealing member 300, and an upper redistribution wiring layer 400. The first package may be substantially the same as or similar to the unit package described with reference to FIG. 31.

In example embodiments, the second package 500 may include a second package substrate 510, a plurality of second semiconductor chips 520 mounted on a second package substrate 510, and a sealing member 540 covering second semiconductor chips 520 on a second package substrate 510.

The second package 500 may be stacked on the first package through conductive connection members 550. For example, the conductive connection members 550 may include solder balls, conductive bumps, etc. The conductive connection member 550 may be disposed between a bonding pad on a second upper redistribution wiring 422 of an upper redistribution wiring layer 400 and a second connection pad 514 of the second package substrate 510. Thus, the first package and the second package 500 may be electrically connected to each other by the conductive connection members 550.

A plurality of second semiconductor chips 520a, 520b, 520c, and 520d may be sequentially stacked on the second package substrate 510 by adhesive members. Bonding wires 530 may connect second chip pads 522 of the second semiconductor chips 520 to first connection pads 512 of the second package substrate 510. The second semiconductor chips 520 may be electrically connected to the second package substrate 510 by the bonding wires 530.

The second package 500 includes four semiconductor chips mounted by wire bonding method, but it may be understood that the number of the above semiconductor chips in the second package and the mounting method are not limited thereto.

In an embodiment, a heat sink may be provided on the second package 500 to dissipate heat from the first package and the second package to the outside. The heat sink may be attached to the second package 500 by a thermal interface material (TIM).

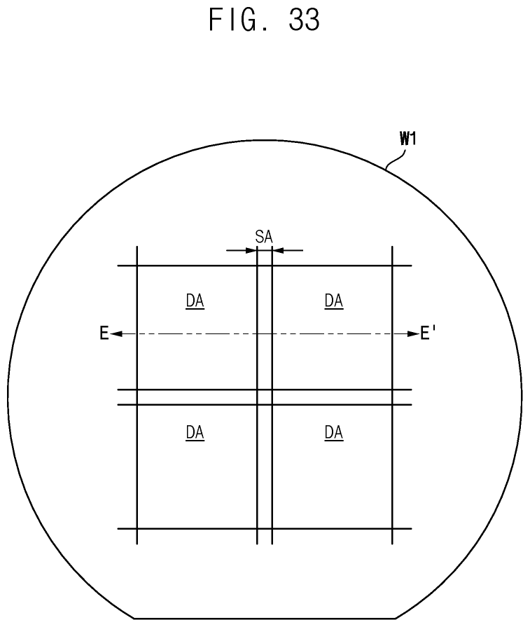

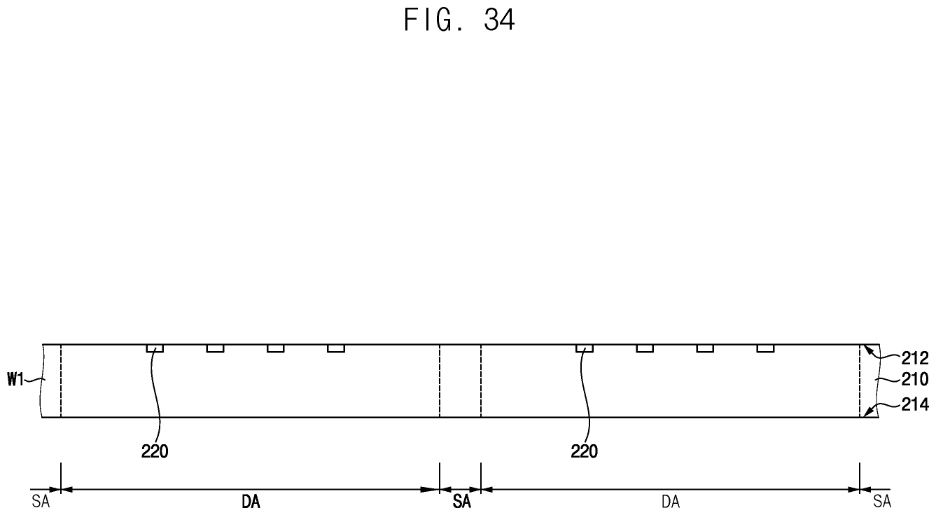

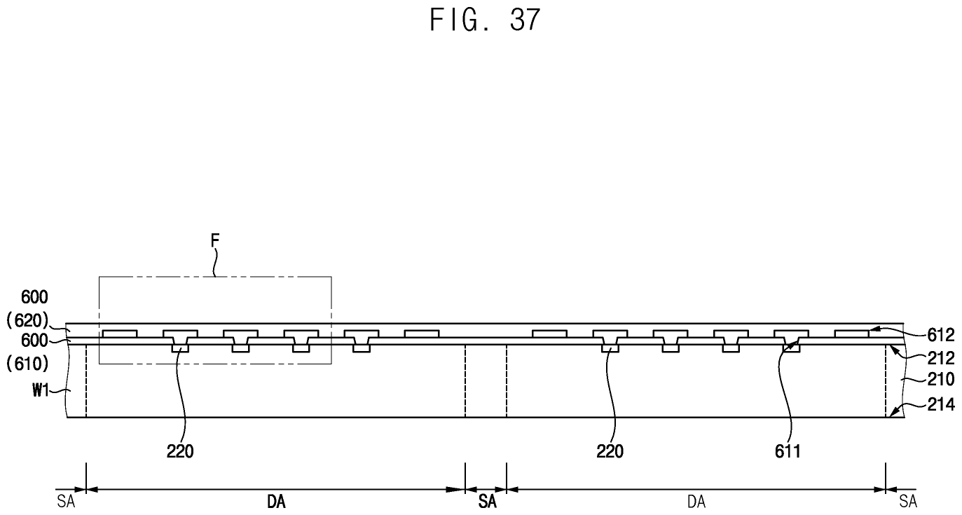

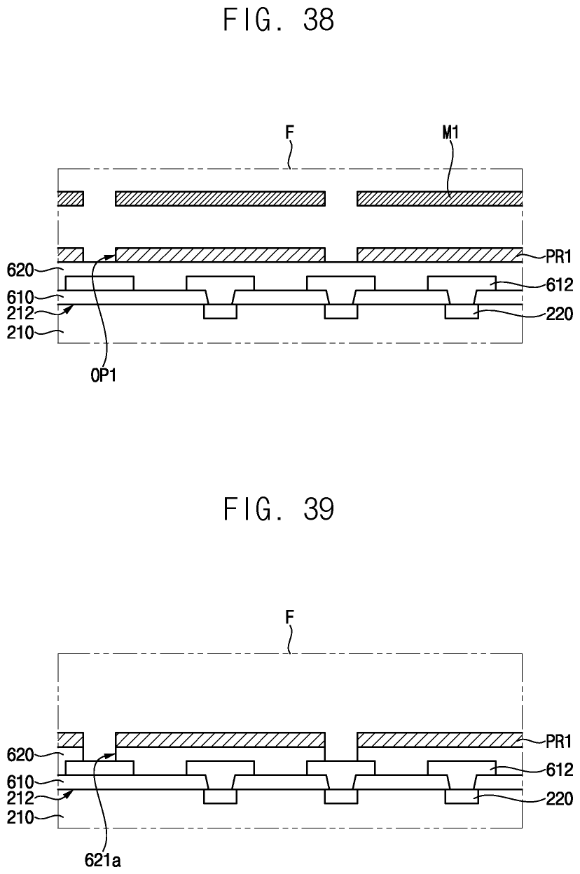

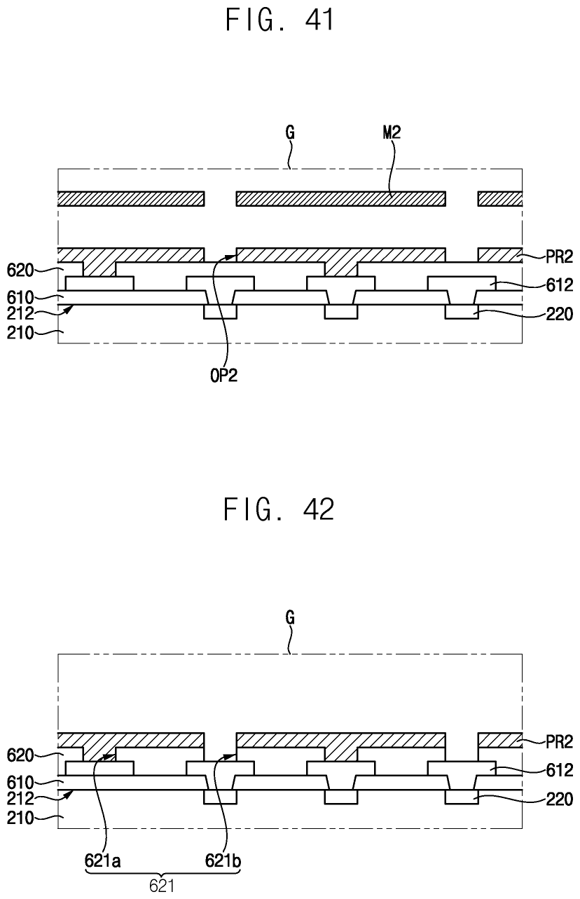

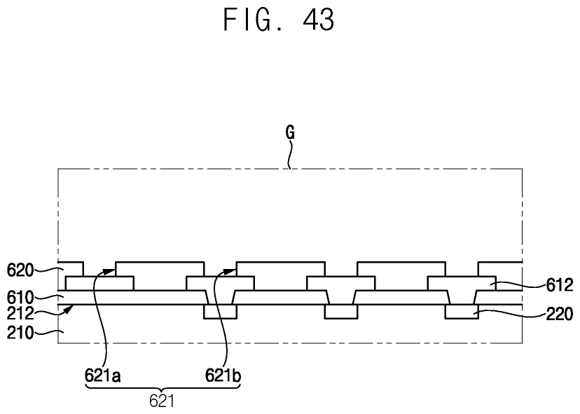

FIGS. 33 to 47 are views illustrating a method of manufacturing a semiconductor package in accordance with example embodiments. FIG. 33 is a plan view illustrating a wafer in which semiconductor chips are formed. FIGS. 34 to 37, 40, and 44 to 46 are cross-sectional views taken along the line E-E″ in FIG. 33. FIGS. 38 and 39 are enlarged cross-sectional views illustrating portion ‘F’ in FIG. 37. FIGS. 42 and 43 are enlarged cross-sectional views illustrating portion ‘G’ in FIG. 41.

Referring to FIGS. 33 and 34, first, a semiconductor wafer W1 in which a plurality of semiconductor chips are formed may be provided.

In example embodiments, the wafer W1 may include a substrate 210 having a first surface 212 and a second surface 214 opposite to the first surface 212. The substrate 210 may include a die region DA and a scribe lane region SA surrounding the die region DA. The substrate 210 may be cut along the scribe lane region SA that divides the plurality of die regions DA of the wafer W1 by a subsequent sawing process to be individualized into a plurality of semiconductor chips.

Circuit elements may be formed in the die region DA on the first surface 212 of the substrate 210. For example, the circuit device may include an integrated circuit for performing power source-related functions such as power management semiconductors, battery management, and DC-DC converters.

Alternatively, the circuit element may include a plurality of memory elements. Examples of the memory device include a volatile semiconductor memory device and a nonvolatile semiconductor memory device. Examples of the volatile semiconductor memory device include DRAM, SRAM, etc. Examples of the nonvolatile semiconductor memory device include an EPROM, an EEPROM, and a Flash EEPROM.

For example, the substrate 210 may include semiconductor materials such as silicon, germanium, silicon-germanium, or group III-V compounds such as gallium phosphide (GaP), gallium arsenic (GaAs), gallium antimonide (GaSb), etc. In some embodiments, the substrate 210 may be a silicon-on-insulator (SOI) substrate or a germanium-on-insulator (GOI) substrate.

The circuit elements may include, for example, a transistor, a capacitor, a wiring structure, etc. The circuit elements may be formed on the first surface 212 of the substrate 210 by performing a Fab process called a front end of line (FEOL) for semiconductor device manufacturing. A surface of the substrate on which the FEOL process is performed may be referred to as a front side surface of the substrate, and an opposite surface of the front surface may be referred to as a backside surface. An insulation interlayer covering the circuit elements may be formed on the first surface 212 of the substrate 210.

In example embodiments, a plurality of chip pads 220 may be formed on the first surface 212 of the substrate 210. The chip pads 220 may be electrically connected to the circuit elements through contact plugs in the insulation interlayer. A passivation layer may be formed on the insulation interlayer on the first surface 212 of the substrate 210. At least portions of the chip pads 220 may be exposed by the passivation layer.

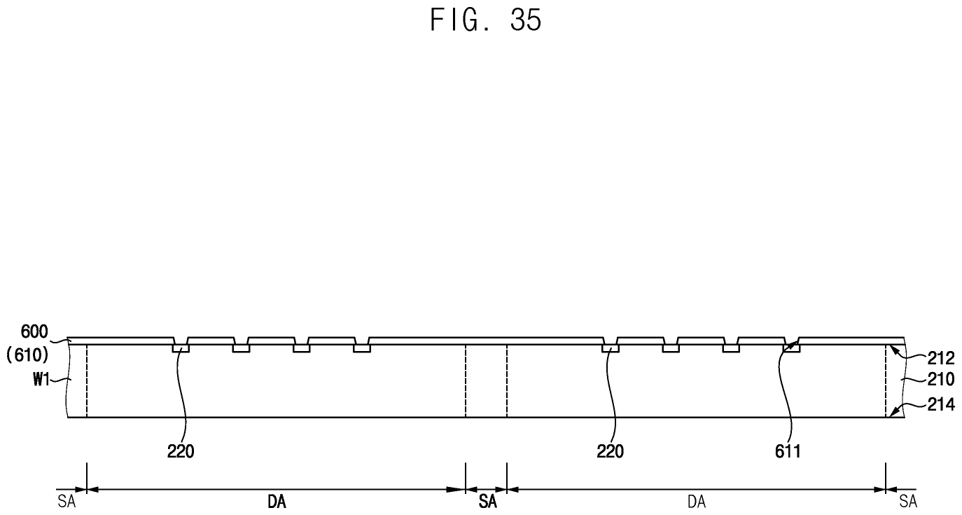

Referring to FIGS. 35 to 45, a redistribution wiring layer 600 may be formed on the first surface 212 of the substrate 210. The redistribution wiring layer 600 may include at least one insulation layer 610, 620, 630 and redistribution wirings 602 provided in the at least one insulation layer and electrically connected to the chip pads 220.

As illustrated in FIG. 35, a first insulating layer 610 having first openings 611 that expose the chip pads 220 may be formed on the first surface 212 of the substrate 210. The first insulating layer may include a polymer, a dielectric layer, etc. For example, the first insulating layer may include a photosensitive dielectric layer such as PID (photo imageable dielectric). The first insulating layer may be formed by a vapor deposition process, a spin coating process, etc.

When the first insulating layer includes a photosensitive dielectric layer such as PID, the photosensitive dielectric layer may be formed on the first surface 212 of the substrate 210, and then the photosensitive dielectric layer may be patterned to form preliminary openings that expose the chip pads. Patterning of the photosensitive dielectric layer may be performed by an exposure process and a development process. Subsequently, a curing process of the photosensitive dielectric layer may be performed, such that a portion of the photosensitive dielectric layer flows toward the preliminary opening to form the tapered first opening 611.

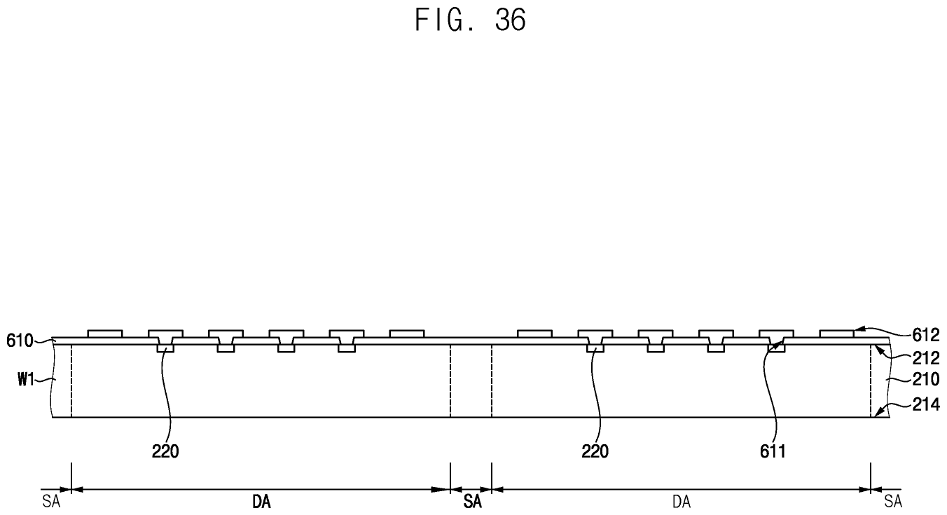

As illustrated in FIG. 36, first redistribution wirings 612 may be formed on the first insulating layer 610 to be electrically connected to the chip pads 220 through the first openings 611.

For example, a seed layer may be formed on the first insulating layer 610 and the chip pads 220 in the first opening 611, a photoresist pattern having openings that expose first redistribution wiring regions may be formed on the seed layer, and the first redistribution wirings 612 may be formed in the openings of the photoresist pattern. Subsequently, the photoresist pattern may be removed by a strip process. The first redistribution wiring 612 may be electrically connected to the chip pad 220 through the first opening 611 of the first insulating layer 610.

The first redistribution wiring may contain copper (Cu), aluminum (Al), tin (Sn), nickel (Ni), gold (Au), platinum (Pt), or an alloy thereof. Alternatively, the first redistribution wiring may be formed by a vapor deposition process etc.

As illustrated in FIG. 37, a second insulating layer 620 covering the first redistribution wirings 612 may be formed on the first insulating layer 610. For example, the second insulating layer 620 may include a polymer, a dielectric layer, etc. The second insulating layer 620 may include a photosensitive insulating material (PID), an insulating film such as ABF, etc. The second insulating layer may be formed by a spin coating process, a vapor deposition process, etc.

When the second insulating layer includes a photosensitive insulating material, a photosensitive insulating material layer may be formed on the first insulating layer 610 by a spin coating process, and a curing process of the photosensitive insulating material layer may be performed. The photosensitive insulating material layer may be changed into an insulating material layer by the curing process. The insulating material layer may include an insulating material having a low dielectric constant. Thus, the second insulating layer on which the curing process has been performed may lose a photoresist property that reacts to light.

As illustrated in FIG. 38, a first photo etching process may be performed on the second insulating layer 620 to form first via holes 621. The first photoresist layer may be formed on second lower insulating layer 120, an exposure process using the first exposure mask M1 may be performed on the first photoresist layer, and a development process may be performed to form a first photoresist pattern PR1 having first opening patterns OP1 that exposing first via regions.

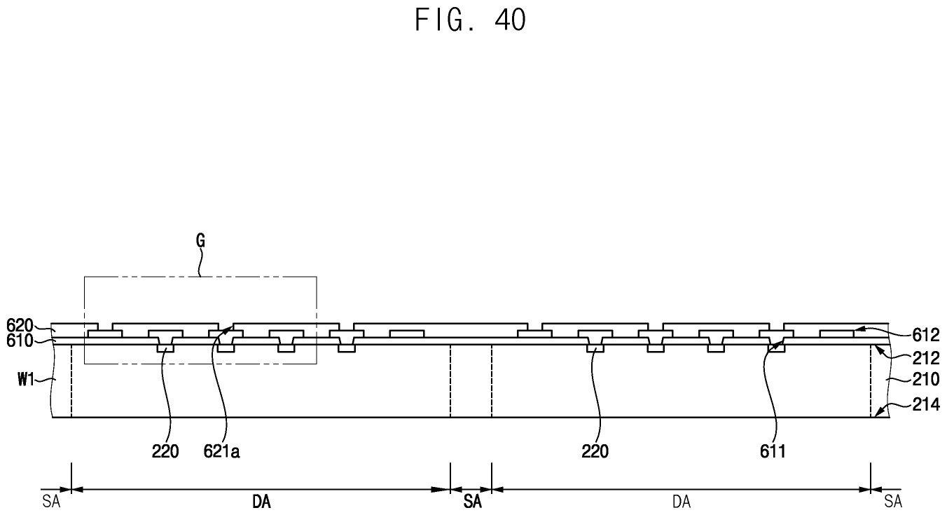

As illustrated in FIGS. 39 and 40, the second insulating layer 620 may be etched using a first photoresist pattern PR1 as an etching mask to form the first via holes 621a. The first via holes 621a may be etched by an isotropic etching process. Then, the first photoresist pattern PR1 may be removed from the second insulating layer 620 by an ashing process and a strip process. The first via holes 621a may expose only first portions of the first redistribution wirings 612 under the second insulating layer 620.

As illustrated in FIG. 41, a second photo etching process may be performed on the second insulating layer 620 to form second via holes 621b. The second photoresist layer may be formed on the second insulating layer 620, an exposure process using a second exposure mask M2 may be performed on the second photoresist layer, and a development process may be performed to form a second photoresist pattern PR2 having second opening patterns OP2 that expose second via regions.

As illustrated in FIGS. 42 and 43, the second insulating layer 620 may be etched using the second photoresist pattern PR2 as an etching mask to form the second via holes 621b. The second via holes 621b may be etched by an isotropic etching process. Then, the second photoresist pattern PR2 may be removed from the second insulating layer 620 by an ashing process and a strip process. The second via holes 621b may expose only second portions of the first redistribution wiring 612 under the second insulating layer 620. Thus, second openings 621 including first via holes 621a and second via holes 621b may be formed in the second insulating layer 620.

The first via holes 621a and the second via holes 621b may be alternately arranged in one direction. The first via holes 621a and the second via holes 621b may be formed through a double patterning process including two etching processes. For example, at least one of the first via hole 621a and the second via hole 621b may have a diameter of 1 μm to 8 μm. The first via hole 621a and the second via hole 621b may have the same diameter. Alternatively, the diameter of the first via hole 621a may be greater than or less than the diameter of the second via hole 621b.

The second openings 621 having fine diameters and pitches may be formed by dividing the second openings 621 into the first via holes 621a and the second via holes 621b respectively formed by the first photo etching process and the second photo etching process. Thus, the limitation of the resolution of the PID insulating layer lower than the resolution of the conventional photoresist pattern may be overcome.

The first openings 611 of the first insulating layer 610 may be formed by patterning the first insulating layer by performing an exposure process and a development process on the first insulating layer 610, but may not be limited thereto. For example, the first openings 611 of the first insulating layer 610 may be formed by processes the same as or similar to the processes described with reference to FIGS. 37 to 43. That is, the first openings 611 of the first insulating layer 610 may be formed through a double patterning process including two etching processes.

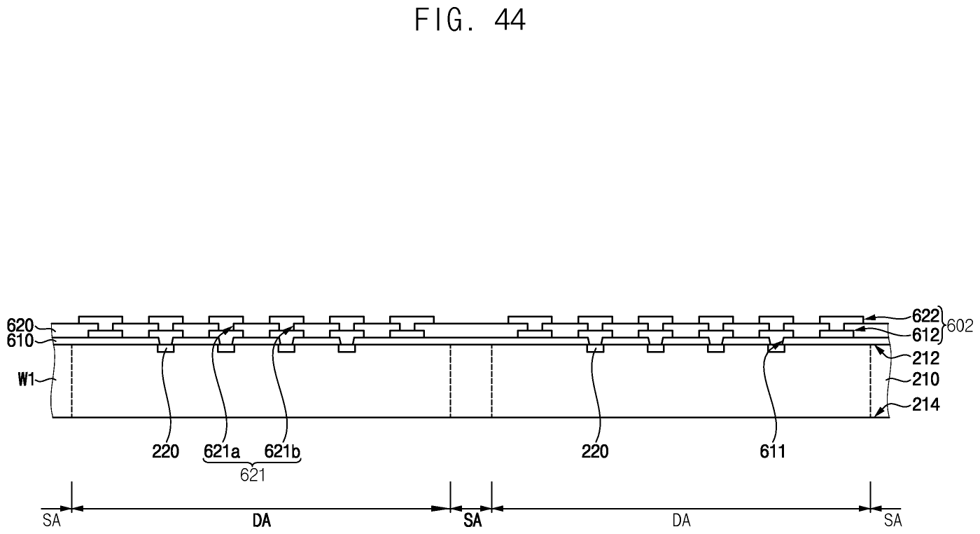

As illustrated in FIG. 44, second redistribution wirings 622 may be formed on the second insulating layer 620. The second redistribution wirings 622 may be electrically connected to the first redistribution wirings 612 through the second openings 621 of the second insulating layer 620.

In example embodiments, a barrier layer and a seed layer may be sequentially formed on the second insulating layer 620. The barrier layer may be formed on a sidewall of the second opening 621 of the second insulating layer 620 and a portion of the first redistribution wiring 612 exposed by the second opening 621.

Subsequently, a photoresist layer may be formed on the seed layer, and an exposure process and a development process may be performed on the photoresist layer to form a photoresist pattern having openings that expose second redistribution regions. A second plating pattern may be formed in the opening of the photoresist pattern, and the photoresist pattern may be removed from the second insulating layer 620. The second plating pattern may be formed by an electroplating process or an electroless plating process.

Then, a portion of the seed layer exposed by the second plating pattern may be removed to form a second seed layer pattern. A portion of the seed layer exposed by the second plating pattern may be removed by an isotropic etching process.

Subsequently, a portion of the barrier layer exposed by the second seed layer pattern may be removed to form a second barrier layer pattern. A portion of the barrier layer exposed by the second plating pattern may be removed by an anisotropic etching process.

Thus, a second redistribution wiring 622 including the second barrier layer pattern, the second seed layer pattern, and the second plating pattern may be formed on the second insulating layer 620. The second redistribution wiring 622 may include a second redistribution via, a second redistribution line, and a second redistribution pad. The second redistribution via may be formed in the second opening 621 of the second insulating layer 620. The second redistribution line may extend on the second insulating layer. The second redistribution pad may be provided in a portion of the second redistribution line.

Thus, the redistribution wirings 602 may include the first redistribution wiring 612 and the second redistribution wiring 622, which are stacked in two layers. In this case, the second redistribution wiring 622 may correspond to the uppermost redistribution wiring among the redistribution wirings.

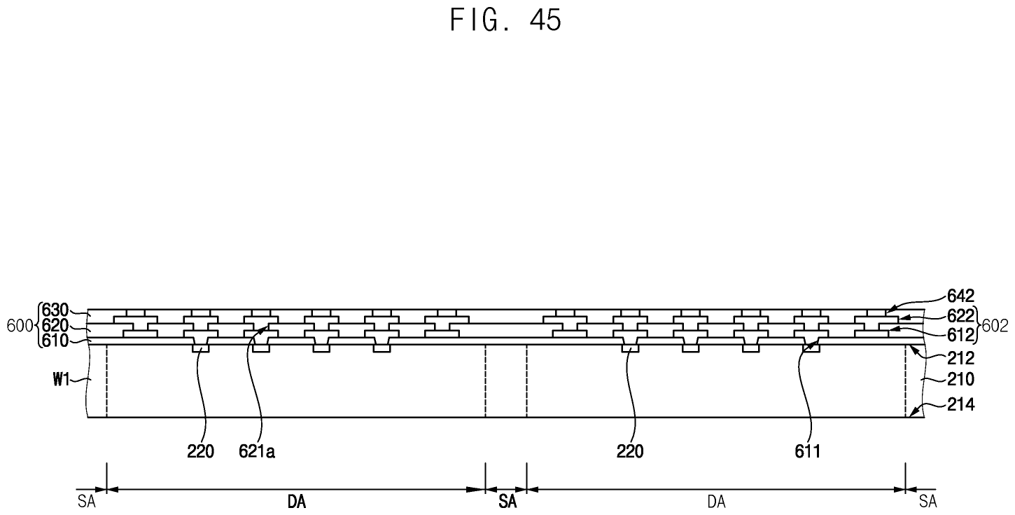

As illustrated in FIG. 45, UBM pads 642 may be formed on the second redistribution wirings 622 as the uppermost redistribution wirings, and a third insulating layer 630 may be formed on the second insulating layer 620 to expose at least a portion of the UBM pad on the second redistribution wiring 622. The third insulating layer 630 may serve as a passivation layer.

Thus, the redistribution wiring layer 600 having the first to third insulating layers 610, 620, 630 may be formed. The redistribution wiring layer 600 may be a redistribution wiring layer of a chip scale package. The UBM pads may be exposed from an upper surface of the redistribution wiring layer 600.

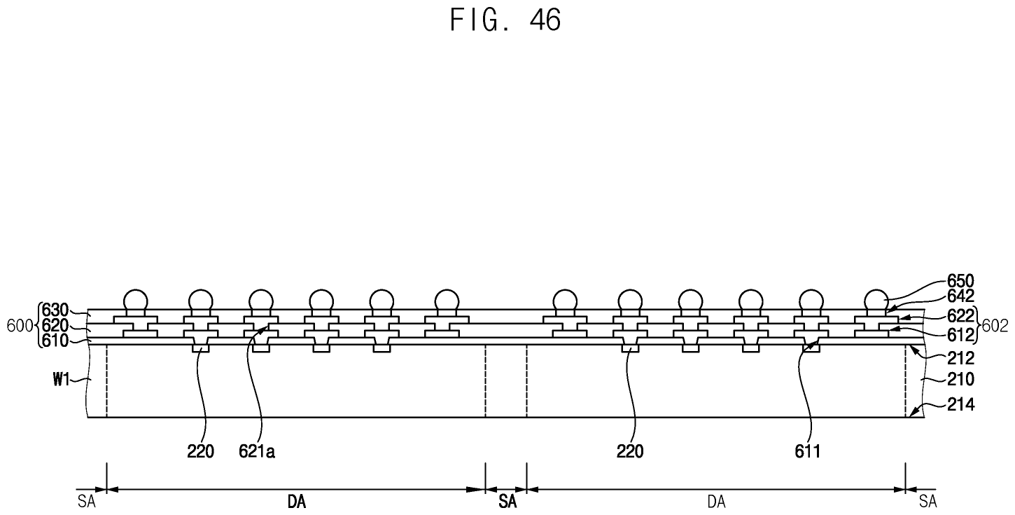

Referring to FIG. 46, conductive bumps 650 as external connection members may be formed on the redistribution wiring layer 600 to be electrically connected to the redistribution wirings 602.

For example, the conductive bumps 650 may be respectively formed on the UBM pads 642 by a ball attach process. The conductive bump 650 may be formed by coating flux on a solder bump or a solder ball and performing a reflow process.

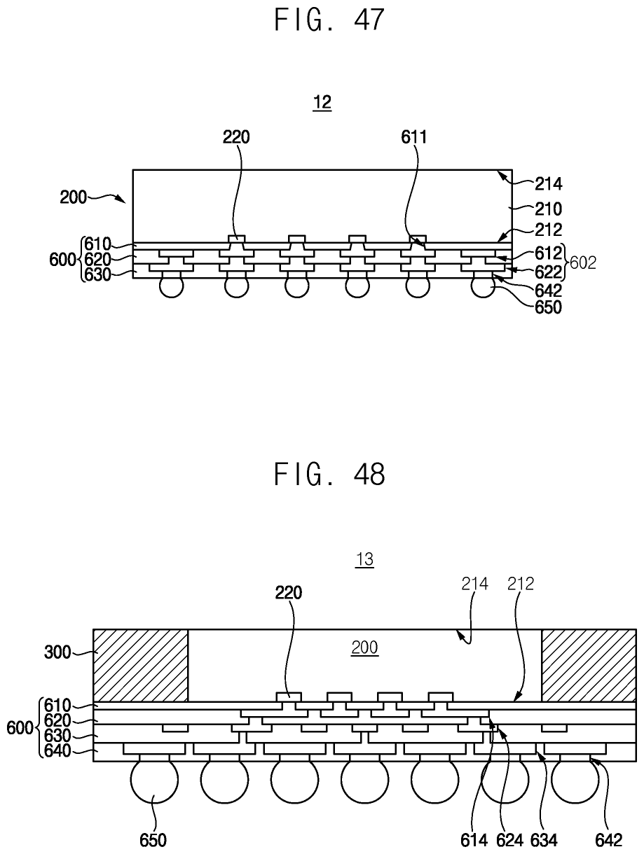

Referring to FIG. 47, the wafer may be cut along the scribe lane region SA that divides the plurality of die regions DA to complete a semiconductor package 12 that includes the redistribution wiring layer 600 formed on an individualized semiconductor chip 200. The semiconductor package 12 may include the semiconductor chip 200, the redistribution wiring layer 600 disposed on one surface of the semiconductor chip 200, and external connection members 650 placed on the outer surface of the redistribution wiring layer 600.

In example embodiments, the semiconductor package 12 may be a wafer level chip scale package (WLCSP). The semiconductor chip 200 of the semiconductor package 12 may include a power management integrated circuit (PMIC). The semiconductor chips 200 may include integrated circuits for performing power source-related functions such as power management semiconductors, battery management, and DC-DC converters.

FIG. 48 is a cross-sectional view illustrating a semiconductor package in accordance with embodiments. The semiconductor package is substantially the same as the semiconductor package described with reference to FIG. 47 except for a structure of a redistribution wiring layer and an additional of a sealing member. The semiconductor package in FIG. 48 may be formed by performing processes the same as or similar to the processes described with reference to FIGS. 33 to 47.

Referring to FIG. 48, the semiconductor package 13 may include a redistribution wiring layer 600, a semiconductor chip 200 disposed on a first surface of the redistribution wiring layer 600, a sealing member 300 covering at least one side of the semiconductor chip 200 on the first surface of the redistribution wiring layer 600, and external connection members 650 disposed on a second surface of the second surface of the redistribution wiring layer 600.

Hereinafter, a method of manufacturing the semiconductor package in FIG. 48 will be described.

First, after semiconductor chips 200 are arranged on a wafer substrate, a sealing member 300 may be formed on the wafer substrate to cover the semiconductor chips 200.

In example embodiments, the wafer substrate may include a package region MR on which the semiconductor chip 200 is mounted and a cutting region CR surrounding the mounting region MR. As will be described later, the sealing member formed on the wafer substrate may be cut along the cutting region CR that divides the plurality of package regions MR to be individualized.

The semiconductor chips 200 may be arranged such that a second surface 214 opposed to a first surface 212 on which chip pads 220 are formed faces the wafer substrate.

Subsequently, the sealing member 300 covering a side surface of the semiconductor chip 200 may be formed on the wafer substrate. For example, the sealing member 300 may include an epoxy mold composite (EMC). The sealing member 300 may expose the first surface 212 of the semiconductor chip 200 and cover only the side surface of the semiconductor chip 200.

Then, processes the same as or similar to the processes described with reference to FIGS. 35 to 45 may be performed to form a redistribution wiring layer 600 on the first surface 212 and the sealing member 300 of the semiconductor chip 200.

The redistribution wiring layer 600 may include a first insulation layer 610, a second insulation layer 620, a third insulation layer 630, and a fourth insulation layer 640. The redistribution wirings 602 are provided in the first insulation layer 610, the second insulation layer 620, the third insulation layer 630, and the fourth insulation layer 640. The redistribution wirings 602 may include a first redistribution wiring 612, a second redistribution wiring 622, and a third redistribution wiring 632, which are stacked in three layers.

The first insulating layer 610 may be provided on the first surface 212 of the semiconductor chip 200 and the sealing member 300, and may have first openings that expose the chip pads 220 of the semiconductor chip 200, respectively. The first redistribution wirings 612 may be provided on the first insulating layer 610 and may be electrically connected to the chip pads 220 through the first openings, respectively.

The first openings of the first insulating layer 610 may be formed by performing an exposure process and a development process on the first insulating layer to pattern the first insulating layer and performing a curing process of the first insulating layer. Alternatively, the first openings of the first insulating layer 610 may be formed by processes the same as or similar to the processes described with reference to FIGS. 37 to 43. That is, the first openings of the first insulating layer 610 may be formed through a double patterning process including two etching processes.

The second insulating layer 620 may be provided on the first insulating layer 610 and may have second openings that respectively expose the first redistribution wirings 612. The second redistribution wirings 622 may be provided on the second insulating layer 620 and may be electrically connected to the first redistribution wirings 612 through the second openings, respectively.

The second openings of the second insulating layer 620 may be formed by processes the same as or similar to the processes described with reference to FIGS. 37 to 43. That is, the second openings of the second insulating layer 620 may be formed through a double patterning process including two etching processes.

The third insulating layer 630 may be provided on the second insulating layer 620 and have third openings that respectively expose the second redistribution wirings 622. The third redistribution wirings 632 may be provided on the third insulating layer 630 and may be electrically connected to the third redistribution wirings 632 through the third openings, respectively.

The third openings of the third insulating layer 630 may be formed by processes the same as or similar to the processes described with reference to FIGS. 37 to 43. That is, the third openings of the third insulating layer 630 may be formed through a double patterning process including two etching processes.

Subsequently, UBM pads 642 may be formed on the third redistribution wirings 632 as the uppermost redistribution wirings, and a fourth insulating layer 640 may be formed on the third insulating layer 630 to expose at least a portion of the UBM pads on the third redistribution wiring 632. The fourth insulating layer 640 may serve as a passivation layer.

Subsequently, processes the same as or similar to the processes described with reference to FIG. 46 may be performed to form conductive bumps 650 as external connection members on the redistribution wiring layer 600 and electrically connected to the redistribution wirings 602.

For example, the conductive bumps 230 may be respectively formed on the UBM pads 250 by a ball attach process. The conductive bump 230 may be formed by coating flux on a solder bump or a solder ball and performing a reflow process.

Then, the wafer substrate may be cut along the cutting region CR that divides the plurality of mounting regions MR to complete a semiconductor package 13 in FIG. 48 including a fan-out type redistribution wiring layer 600.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present disclosure. Accordingly, all such modifications are intended to be included within the scope of example embodiments as defined in the claims.

What is claimed is:

1. A method of manufacturing a semiconductor package, the method comprising:
forming a plurality of lower redistribution wiring layers comprising first redistribution wirings stacked in at least two layers of the plurality of lower redistribution wiring layers;
mounting a semiconductor chip on the plurality of lower redistribution wiring layers, the semiconductor chip comprising chip pads that are electrically connected to the first redistribution wirings;
forming a sealing member covering the semiconductor chip on the plurality of lower redistribution wiring layers;
forming a plurality of through-vias penetrating the sealing member, the plurality of through-vias being electrically connected to the first redistribution wirings; and
forming a plurality of upper redistribution wiring layers on the sealing member, the plurality of upper redistribution wiring layers comprising second redistribution wirings electrically connected to the plurality of through-vias,
wherein the forming the plurality of lower redistribution wiring layers comprises:
forming a first insulating layer;
performing a first photo etching process on the first insulating layer to form first via holes;
performing a second photo etching process on the first insulating layer to form second via holes; and
forming first lower redistribution wirings on the first insulating layer, the first lower redistribution wirings being electrically connected to first bonding pads under the first insulating layer through the first via hole and the second via hole.

2. The method of claim 1, wherein the first insulating layer comprises a photosensitive insulating material.

3. The method of claim 2, wherein the forming the first insulating layer comprises:
coating a photosensitive insulating material layer of the first insulating layer; and
performing a curing process on the photosensitive insulating material layer.

4. The method of claim 1, wherein the performing the first photo etching process on the first insulating layer comprises:
forming a first photoresist layer on the first insulating layer;
performing an exposure process on the first photoresist layer using a first exposure mask;
performing a development process to form a first photoresist pattern having first opening patterns corresponding to the first via holes;
etching the first insulating layer using the first photoresist pattern as a first etching mask to form the first via holes; and
removing the first photoresist pattern.

5. The method of claim 4, wherein the etching the first insulating layer to form the first via holes comprises performing an isotropic etching process using the first photoresist pattern as the first etching mask on the first insulating layer.

6. The method of claim 1, wherein the performing the second photo etching process on the first insulating layer comprises:
forming a second photoresist layer on the first insulating layer;
performing an exposure process on the second photoresist layer using a second exposure mask; and
performing a development process to form a second photoresist pattern having second opening patterns corresponding to the second via holes;
etching the first insulating layer using the second photoresist pattern as a second etching mask to form the second via holes; and
removing the second photoresist pattern.

7. The method of claim 6, wherein etching the first insulating layer to form the second via holes comprises performing an isotropic etching process using the second photoresist pattern as the second etching mask on the first insulating layer.

8. The method of claim 1, wherein at least one sidewall of the first via hole and the second via hole has an angle range of 85 degrees to 105 degrees with respect to a lower surface of the first insulating layer.

9. The method of claim 1, wherein at least one of the first via hole and the second via hole has a diameter of 1 μm to 8 μm.

10. The method of claim 1, wherein the forming the plurality of upper redistribution wiring layers comprises:
forming a second insulating layer;
performing a third photo etching process on the second insulating layer to form third via holes;
performing a fourth photo etching process on a third insulating layer to form fourth via holes; and
forming first upper redistribution wirings on the second insulating layer, the first upper redistribution wirings being electrically connected to second bonding pads under the second insulating layer through the third via hole and the fourth via hole.

11. A method of manufacturing a semiconductor package, the method comprising:
providing a substrate comprising a plurality of semiconductor chips, each of the plurality of semiconductor chips comprising chip pads on a first surface of the semiconductor chip;
forming a plurality of redistribution wiring layers on the first surface of the semiconductor chip, the plurality of redistribution wiring layers comprising redistribution wirings stacked in at least two layers of the plurality of redistribution wiring layers, the redistribution wiring being electrically connected to the chip pads;
forming conductive bumps on an outer surface of the plurality of redistribution wiring layers;
wherein the forming the plurality of redistribution wiring layers comprises:
forming a first insulating layer;
performing a first photo etching process on the first insulating layer to form first via holes;
performing a second photo etching process on the first insulating layer to form second via holes; and
forming first lower redistribution wirings on the first insulating layer, the first lower redistribution wirings being electrically connected to first bonding pads under the first insulating layer through the first via hole and the second via hole.

12. The method of claim 11, wherein the first insulating layer comprises photosensitive insulating material.

13. The method of claim 12, wherein the forming the first insulating layer comprises:
coating a photosensitive insulating material layer of the first insulating layer; and
performing a curing process on the photosensitive insulating material layer.

14. The method of claim 11, wherein performing the first photo etching process on the first insulating layer comprises:
forming a first photoresist layer on the first insulating layer;
performing an exposure process on the first photoresist layer using a first exposure mask;
performing a development process to form a first photoresist pattern having first opening patterns corresponding to the first via holes;
etching the first insulating layer using the first photoresist pattern as a first etching mask to forming the first via holes; and
removing the first photoresist pattern.

15. The method of claim 11, wherein the performing the second photo etching process on the first insulating layer comprises:
forming a second photoresist layer on the first insulating layer;
exposing the second photoresist layer using a second exposure mask;
performing exposure process to form a second photoresist pattern having second opening patterns corresponding to the second via holes;
forming the second via holes by etching the first insulating layer using the second photoresist pattern as a second etching mask; and
removing the second photoresist pattern.

16. The method of claim 11, wherein at least one sidewall of the first via hole and the second via hole has an angle range of 85 degrees to 105 degrees with respect to a lower surface of the first insulating layer.

17. The method of claim 11, wherein at least one of the first via hole and the second via hole has a diameter of 1 μm to 8 μm.

18. A method of manufacturing a semiconductor package, the method comprising:
forming a first photoresist layer on a first insulating layer;
forming a first photoresist pattern having first opening patterns using a first exposure mask;
etching the first insulating layer using the first photoresist pattern as a first etching mask to form first via holes;
removing the first photoresist pattern;
forming a second photoresist layer on the first insulating layer;
forming a second photoresist pattern having second opening patterns using a second exposure mask;
etching the first insulating layer using the second photoresist pattern as a second etching mask to form second via holes;
removing the first photoresist pattern;
forming a redistribution wiring layer on the first insulating layer, the redistribution wiring layer having first redistribution wirings that are electrically connected to first bonding pads under the first insulating layer through the first via hole and the second via hole; and
mounting a semiconductor chip on the redistribution wiring layer, the semiconductor chip comprising chip pads electrically connected to the first redistribution wirings.

19. The method of claim 18, wherein the first insulating layer comprises a photosensitive insulating material.

20. A method of claim 19, wherein the forming the first insulating layer comprises:
coating a photosensitive insulating material layer of the first insulating layer; and
performing a curing process on the photosensitive insulating material layer.
